(19) United States
(12) Patent Application Publication
(10) Pub. No.: US 2025/0298846 A1
(43) Pub. Date: Sep. 25, 2025

(54) FULL-TEXT SEARCH PROCESSOR

(71) Applicant: Katsumi INOUE, Chiba (JP)

(72) Inventor: Katsumi INOUE, Chiba (JP)

(21) Appl. No.: 18/860,340

(22) PCT Filed: Apr. 25, 2023
(86) PCT No.: PCT/JP2023/016310

§ 371 Date: Oct. 25, 2024

(30) Foreign Application Priority Data
Apr. 26, 2022 (JP) 2022-072188
Sep. 15, 2022 (JP) 2022-147080

(51) Int. Cl. G06F 16/903; G06F 16/9038

(52) U.S. Cl. CPC G06F 16/90344; G06F 16/9038

(57) ABSTRACT

[Problem to solve]

To provide a hardware accelerator processor for full-text searches.

[Solution]

There is provided a full-text search processor, comprising: character storage elements for assigning and temporarily storing therein, search target text data to be searched through to a first address to an Nth address byte by byte; character detection circuits for receiving coded characters included in the search keyword byte by byte as comparison data, and sequentially detecting storage positions, on the character storage elements, of all of coded characters included in a search keyword; character string detection circuits for sequentially detecting positions, on the character storage elements, of coded characters which match a sequence of all of the coded characters included in the search keyword; and result output circuits for receiving search results of the character string detection circuits and outputting a position of the beginning or a position of the end of the character string that matches the search keyword.

### FIELD OF THE INVENTION

This invention relates to a full-text search processor for performing full-text search using keywords for text data in a semiconductor device.

### BACKGROUND OF THE INVENTION

In general, the process of finding specific data of documents and the like from a large amount of data of documents and the like (including text, literature, sentences, etc.) is called full-text search and/or keyword search, and is frequently utilized in all fields from web search, patent information search, in-house data search, and even PCs and smartphones.

Here, full-text search and/or keyword search are the basic information processing of natural language processing.

In processes of the full-text search, a keyword (a character or a character string as a key of “search,” “retrieve,” “information,” or the like) is given as a search condition, the character or character string is searched to determine whether or not it is included in documents and the like, and data of the documents and the like including the keyword are identified.

CPUs and/or GPUs, which are conventional processors, are generally not good at processing of finding information such as in search or the like, and attempting to read and search all document data without headings (indexes) requires a long time. For this reason, usually, a method is used, wherein indexes called inverted indexes are created in advance, and these inverted indexes are utilized to speed up a retrieval, and this is the only method for speeding up retrieval.

Here, inverted indexes are generally created by using dictionary terms as headings (indexes) and/or by using character strings called N-grams as headings (indexes).

When dictionary terms are used as indexes, it is easy to detect words (terms) in English because of the scheme for creating text with a space separating each word (term), which is the so-called “split-writing” system, but in the case of Japanese and Chinese, this “split-writing” system is inapplicable.

Therefore, in the case of Japanese, a complicated method called morphological analysis is employed, which method isolates words (terms) according to the Japanese grammar.

Morphological indexes are characterized by a small number of indexes, but while forward matching works well, full-text search for middle and/or backward matches are difficult, and it is difficult to accommodate new terms such as popular words.

On the other hand, the N-gram index was devised for natural language analysis by Claude Elwood Shannon, a famous founder of information theory.

It is characterized by its ability to handle full-text search for forward, middle, backward, and new term matching, but its disadvantage is that the number of indexes becomes very large.

In light of the above background, various methods have been developed, such as mixing the advantages of the morphological indexing and the N-gram indexing.

Using such indexes enables full-text search and/or keyword search to speed up, but it has several major problems.
Even if text data of documents and the like are prepared, the data is not searchable until inverted indexes are created. Therefore, full-text search of stream information (data) and/or real-time processing of full-text search itself are difficult.
The memory area and/or storage area are expanded for indexes, and expansion is difficult due to the indexes.

Because of the above various problems, full-text search creates a high hurdle for non-specialists, and is difficult to standardize on a global level due to language differences.

Prior art that incorporated full-text search into a semiconductor will be discussed.

US 2010/0185647 A1 discloses a semiconductor device for the purpose of character data search, wherein an XY matrix consisting of a line decoder and feature cells can be as small as 256×256 when only 256 types of characters are supported as in the ASKII code, but in the case of a 3-byte or 4-byte character set, such as Japanese text in the UTF-8 code, the XY matrix becomes very large and is difficult to implement.

Also, this patent is intended for searching stream data such as malware detection, and cannot be utilized for both stored data and stream data as in the present application.

In order to solve the various information detection problems as above, the present inventor has made various inventions by way of in-memory computing, PIM (Process in Memory), and architecture, and has obtained patents as shown in the following Patent Documents 2 through 5.

However, none of the above inventions had an algorithm suitable for full-text search.

### PRIOR ART DOCUMENTS

### Patent Documents

[Patent Document 1] US 2010/0185647 A1, “DEVICES, SYSTEMS, AND METHODS FOR COMMUNICATING PATTERN MATCHING RESULTS OF A PARALLEL PATTERN SEARCH ENGINE”
[Patent Document 2] Japanese Patent No. 4588114. “MEMORY HAVING INFORMATION NARROWING DETECTION FUNCTION, METHOD FOR USING THE SAME, AND DEVICE INCLUDING THE MEMORY”
[Patent Document 3] Japanese Patent No. 5981666, “MEMORY EQUIPPED WITH INFORMATION SEARCH FUNCTION AND USAGE, DEVICE AND INFORMATION PROCESSING METHOD THEREOF”
[Patent Document 4] Japanese Patent No. 6014120, “MEMORY EQUIPPED WITH SET OPERATION FUNCTION AND SET OPERATION PROCESSING METHOD USING THE MEMORY”
[Patent Document 5] Japanese Patent No. 6393852, “DATA COMPARISON ARITHMETIC PROCESSOR AND ARITHMETIC METHOD USING THE PROCESSOR”

### SUMMARY OF THE INVENTION

The purpose of this application is to provide a hardware accelerator processor for full-text search that does not require the creation of indexes like inverted indexes and even has full-text search performance equivalent to that of a system using N-gram inverted indexes, to fundamentally solve various problems faced by full-text search technology, to improve natural language processing technology, and to aim at globally standardize full-text search.

In order to overcome the above challenges, the following invention is provided according to a principal aspect of the present invention.
(1) A full-text search processor consisting of semiconductor devices intended for full-text keyword searches, the full-text search processor comprising:
character storage elements for receiving search target text data to be searched through, and assigning and temporarily storing therein, a coded character string included in the text data to a first address to an Nth address byte by byte;
character detection circuits for detecting storage positions, on the character storage elements, of all of coded characters included in a search keyword by sequentially receiving one or more coded characters included in the search keyword byte by byte as comparison data, comparing each of the comparison data with the coded character string stored on the character storage elements in N-parallel, and repeating it for all of the coded characters included in the search keyword;
character string detection circuits for detecting positions on the character storage elements where all of the coded characters included in the search keyword exist consecutively in the same order as in the search keyword; and result output circuits for receiving search results of the character string detection circuits and outputting a position of the beginning or a position of the end of the consecutive character string.
(2) The full-text search processor of (1), wherein
the character detection circuits comprise
N sets of eight 1-bit match or mismatch operational circuits, connected to each address of the character storage elements, for comparing a 1-byte/8-bit code of the text data stored at each address and a 1-byte/8-bit code constituting the comparison data, and detecting a bit-by-bit match or mismatch; and
N logic operation (logical product (AND), logical sum (OR), and/or logical negation) circuits for receiving 8 bits of result output from each set of the 1-bit match or mismatch operational circuits, and detecting a match or mismatch between the coded characters of the text data stored at each address and coded characters constituting the comparison data.
(3) The full-text search processor of (1), wherein
the character string detection circuit is
composed of two circuits: an FG shift circuit and an FG tournament circuit for consecutively determining validity of a FG (flag) at the character storage position consecutively detected by the character detection circuit and a FG (flag) sequence at the detected character storage positions, and
the FG shift circuit and the FG tournament circuit are circuits for detecting in N-parallel, a position (address) of the beginning or a position (address) of the end of the character string on the character storage elements, which the character string matching the character string specified by the search keyword, by referring to a sequence of coded characters included in the search keyword and repeatedly determining the validity of a sequence of adjacent character codes in the character string on the character storage elements, assigned and stored at the first address to the Nth address.
(4) The full-text search processor of (1), wherein
the character string detection circuits comprise
N of FG shift circuits for storing operation results of the character detection circuits as flags as well as shifting the stored FGs in N-parallel; and
N of FG tournament circuits for performing tournament operations on the FGs by shifting the FGs, stored by the FG shift circuits, in N-parallel while performing N-parallel logic operations on the FGs with the pre-shifting FGs, and repeating the same for all of the coded characters included in the search keyword.
(5) The full-text search processor of (1), wherein
when the search keyword is constituted with n-byte coded characters,
the number of shifts of the FG shift circuits and its associated the number of tournament operations by the FG tournament operational circuits are n−1 times, respectively.
(6) The full-text search processor of (1), wherein
the FG tournament circuits comprise a function for enabling masking (ignoring) of operations and enable a full-text search when a wildcard is used in the search keyword.
(7) The full-text search processor of (1), wherein
the FG tournament circuit is incorporated with two pairs of registers and enable a full-text search when the search keyword includes a character gap.
(8) The full-text search processor of (1), wherein
the full-text search processor performs a logical sum (OR) operation on the N-parallel (full parallel) detection results output by the result output circuits, and outputs presence or absence of full-text search operations.
(9) The full-text search processor of (1), wherein
the full-text search processor transfers text data, which is in memories or storage external to the full-text search processor, to character storage elements, which are for temporarily storing the N-byte character text data, as batch data; and repeats the full-text search operations in N-parallel (full parallel).
(10) The full-text search processor of (1), wherein
the full-text search processor transfers text data, which is in memories or storage inside the full-text search processor, to character storage elements, which are for temporarily storing the N-byte character text data, as batch data; and repeats the full-text search operations in N-parallel (full parallel).
(11) The full-text search processor of (1), wherein
the full-text search processor is implemented in ASICs and FPGAs.
(12) The full-text search processor of (1), wherein the full-text search processor has a CPU incorporated therein.
(13) A method for using the full-text search processor of (1), comprising the step of:
applying a world standard character code such as UTF-8 to thereby enable universal full-text search for all characters worldwide.
(14) The full-text search processor of (1), wherein
when predetermined character codes are included in a character string of an externally given search keyword, the full-text search processor performs or does not perform the full-text search operations.
(15) The full-text search processor of (1), wherein
by matching a part of a sentence being composed with the full-text search processor, which has therein accumulated text data that incorporates a large amount of the latest information, if there is no matching text, the full-text search processor determines that there is no precedent.
(16) The full-text search processor of (1), wherein
when selecting an optimal recognition result among a plurality of recognition candidates of speech recognition, by matching with the full-text search processor, which has therein accumulated text data that incorporates a large amount of the latest information, and selecting terms with the most matching text, the full-text search processor improves accuracy of speech recognition.

Full-text search processing is closely related to our work and/or life, and is crucial information processing, such as in web search, patent search, in-house data search, data search within PCs and/or smartphones.

However, full-text search processing with the current computing has various problems, such as real-time processing is difficult because it must rely on indexes such as inverted indexes; people other than specialists cannot build systems; and differences in languages hinder standardization on a global level.

Using the full-text search processor of the present invention will enable full-text search with no need to use inverted indexes, and with performance comparable to that of a scheme using inverted indexes.

Thus, it will accelerate the evolution of natural language processing (knowledge processing) technology, and enable global standardization of full-text search technology since it can be used universally for languages in all countries.

### BRIEF DESCRIPTION OF THE DRAWINGS

FIG. 1 is a diagram illustrating a basic configuration of a full-text search processor according to one embodiment (a first example) of the present invention;

FIG. 2 is a diagram illustrating a detailed configuration of character storage elements and character detection circuits of the full-text search processor according to the one embodiment (the first example);

FIG. 3 is a diagram illustrating a detailed configuration of character string detection circuits and result output circuits of the full-text search processor according to the one embodiment (the first example);

FIG. 4 is a diagram illustrating specific examples of full-text search operation conditions by a command generation circuit according to the one embodiment (the first example);

FIG. 5 is a diagram illustrating data state transition-A (character detection process) in standard full-text search for English text according to the one embodiment (the first example);

FIG. 6 is a diagram illustrating data state transition-B (character string detection process) in standard full-text search for English text according to the one embodiment (the first example);

FIG. 7 is a diagram illustrating data state transition-A (character detection process) in standard full-text search for Japanese text according to the one embodiment (the first example);

FIG. 8 is a diagram illustrating data state transition-B (character string detection process) in standard full-text search for Japanese text according to the one embodiment (the first example);

FIG. 9 is a diagram illustrating data state transition-A (character detection process) in full-text search with wildcards applied to English text according to the one embodiment (the first example);

FIG. 10 is a diagram illustrating data state transition-B (character string detection process) in full-text search with wildcards applied to English text according to the one embodiment (the first example);

FIG. 11 is a diagram illustrating data state transition-A (character detection process) in full-text search with character gap applied to English text according to the one embodiment (the first example);

FIG. 12 is a diagram illustrating data state transition-B (character string detection process) in full-text search with character gap applied to English text according to the one embodiment (the first example);

FIG. 13 is a diagram illustrating an overall configuration of the full-text search processor according to the one embodiment (the first example);

FIG. 14 is a diagram illustrating a configuration of a full-text search processor when performing refinement searches according to the one embodiment (the first example);

FIG. 15 is a diagram illustrating an overview of an external memory-type full-text search processor according to the one embodiment (the first example);

FIG. 16 is a diagram illustrating an overview of data transfer between an external memory-type full-text search processor and an external memory or storage according to the one embodiment (the first example);

FIG. 17 is a diagram illustrating a time chart of batch processing of the external memory-type full-text search processor according to the one embodiment (the first example);

FIG. 18 is a diagram summarizing computational performance of the external memory-type full-text search processor according to the one embodiment (the first example);

FIG. 19 is a diagram illustrating an overview of an internal memory-type full-text search processor according to the one embodiment (the first example);

FIG. 20 is a diagram summarizing computational performance of the internal memory-type full-text search processor according to the one embodiment (the first example);

FIG. 21 illustrates diagrams of system configuration examples when using full-text search processors according to the one embodiment (the first example);

FIG. 22 is a diagram illustrating a basic configuration of a full-text search processor according to a second example of the one embodiment of the present invention;

FIG. 23 is a diagram illustrating a detailed configuration of character string detection circuits and result output circuits of the full-text search processor according to the second example of the one embodiment;

FIG. 24 is a diagram illustrating specific examples of full-text search operation conditions by a command generation circuit according to the second example of the one embodiment;

FIG. 25 is a diagram illustrating data state transition-A of each function in standard full-text search for English text according to the second example of the one embodiment;

FIG. 26 is a diagram illustrating data state transition-B of each function in standard full-text search for English text according to the second example of the one embodiment;

FIG. 27 is a diagram illustrating data state transition-A of each function in standard full-text search for Japanese text according to the second example of the one embodiment;

FIG. 28 is a diagram illustrating data state transition-B of each function in standard full-text search for Japanese text according to the second example of the one embodiment;

FIG. 29 is a diagram illustrating data state transition-A in full-text search with wildcards applied to English text according to the second example of the one embodiment;

FIG. 30 is a diagram illustrating data state transition-B in full-text search with wildcards applied to English text according to the second example of the one embodiment;

FIG. 31 is a diagram illustrating data state transition-A in full-text search with gaps applied to English text according to the second example of the one embodiment; and

FIG. 32 is a diagram illustrating data state transition-B in full-text search with gaps applied to English text according to the second example of the one embodiment.

### DETAILED DESCRIPTION OF THE INVENTION

One embodiment of the present invention will be described below with reference to accompanying drawings.

The full-text search processor 101, which is an embodiment of the present invention, provides a configuration that may be utilized with any character code and that may moreover achieve advanced and efficient full-text search.

Before describing the configuration of this embodiment, a concept of full-text search implemented in the present invention will be explained.

### (Concept of Full-Text Search of the Present Invention)

First, a character text data 132 contained in a document is expressed using various coded characters, or character codes, such as ASCII (American Standard Code for Information Interchange), Shift-JIS, and UTF-8 (UCS Transformation Format 8).

ASCII uses a 7-bit or 1-byte configuration, Shift-JIS uses a 2-byte configuration, and the international standard UTF-8 uses a variable length. In the case of UTF-8, many Japanese characters have a 3-byte configuration.

Therefore, in general, in order to properly read out character strings contained in document data, it is necessary to identify the character code and, based on that, read out arbitrary character strings.

Also, in order to perform a high-speed full-text search with a short search latency, it is necessary to create inverted indexes based on the character text data 132 and perform a full-text search using these inverted indexes.

Whereas, in this embodiment, the character text data 132 to be searched through is stored in a storage element for each byte (8 bits), “characters” and “character sequences” of a given search keyword 125 are compared in parallel byte by byte for their match or mismatch, and a position (address) of the character text data 132 corresponding to the beginning or end of the given search keyword 125 character string is returned as a full-text search result.

According to this, it is possible to perform full-text searches with a simple circuit configuration regardless of the character code, and it is also possible to perform high-speed full-text searches without creating inverted indexes.

Specific configurations of the present embodiment will be described below.

### Basic Circuit Configuration (First Example)

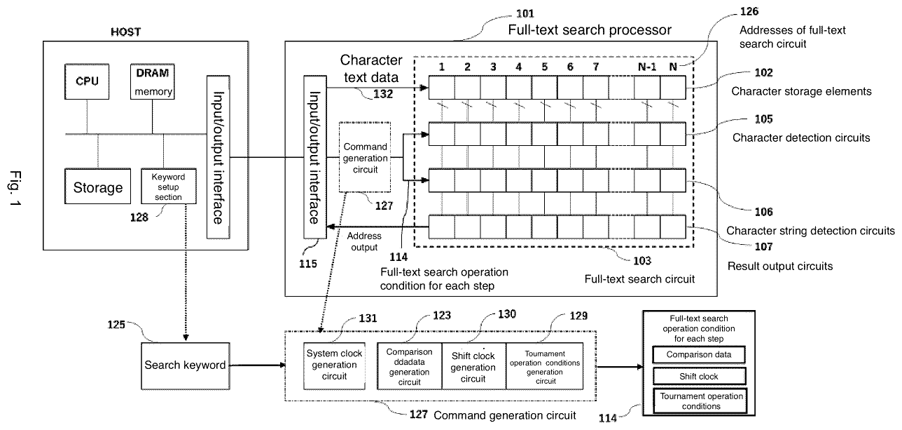

FIG. 1 shows a basic configuration of a full-text search processor.

This full-text search processor 101 is connected to a host computer (hereinafter referred to as “HOST”), and executes parallel full-text search operations with a search keyword 125 given from the HOST as a search condition against character text data 132 as a search target given from the HOST, and returns a location (address) of the character text data 132 detected as a result to the HOST.

In order to execute this process, this full-text search processor 101 has a configuration in which a full-text search circuits 103 and a command generation circuit 127 are connected to an input/output interface 115 connected to the above HOST.

The full-text search circuits 103 each has character storage elements 102 for storing character text data 132 to be searched through, character detection circuits 105 for detecting characters contained in the search keyword 125 from the character text data 132 stored in the character storage elements 102, and character string detection circuits 106 for identifying a position (address) of a character in the character text data 132, wherein the character corresponds to the first or last character of the character string of the search keyword 125, based on the character detection results, and result output circuits 107 for outputting the detection results of the above character string detection circuits 106 in a predetermined format.

The command generation circuit 127 is, as shown enlarged in FIG. 1, constituted with a system clock generation circuit 131 for generating a system clock 131, a comparison data generation circuit 123 for generating comparison data 123 to be given to the character detection circuits 105 based on the search keyword 125, a shift clock generation circuit 130 for determining the timing for providing tournament operation conditions 129 to the character string detection circuits 106 after character detection, and a tournament operation conditions generation circuit 129 for generating the tournament operation conditions 129 to be given to the character string detection circuits 106.

### (Command Generation Circuit)

In the following, configurations of the full-text search circuits 103 and the command generation circuit 127 will be described in detail, but for discussion purposes, first, the command generation circuit 127 will be explained.

The system clock generation circuit 131 of the command generation circuit 127 generates a system clock 131, for example, a continuous clock every 10 n seconds or 20 n seconds, which system clock 131 is fundamental for the full-text search processor 101 to perform full-text search operations at a predetermined operation timing, and the comparison data generation circuit 123, the shift clock generation circuit 130, and the tournament operation conditions generation circuit 129 use (synchronize with) this system clock 131 to operate.

The above comparison data generation circuit 123, shift clock generation circuit 130, and tournament operation conditions generation circuit 129 generate, based on the search keywords 125 set by a keyword setting function 128 of the HOST, full-text search operation conditions 114 given to the character detection circuits 105 and the character string detection circuits 106, which full-text search operation conditions 114 consist of three types of operation conditions: the comparison data 123, the shift clock 130, and the tournament operation conditions 129.

In this embodiment example, the search keywords 125 include English keywords composed of characters each of which is one byte, Japanese keywords composed of characters each of which is three bytes, and/or other multilingual keywords.

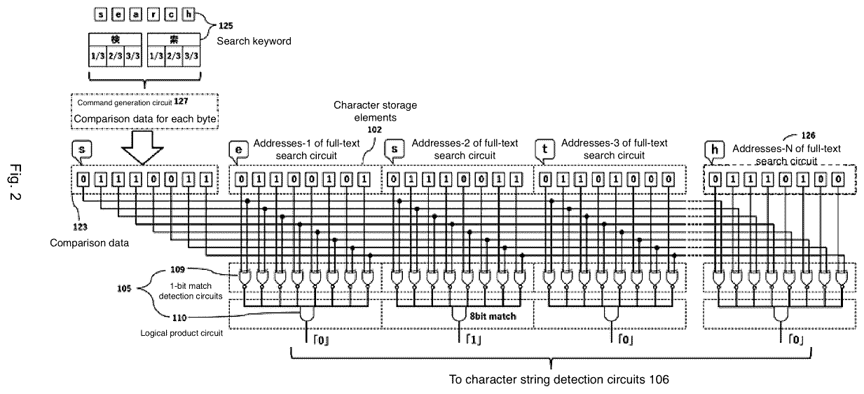

As shown in FIG. 2, for example, if the search keyword 125 is an English word “search,” this keyword is composed of the character codes “s,” “e,” “a,” “r,” “c,” and “h,” each of which is one byte, for a total of six bytes.

Also, if the search keyword 125 consists of two characters of a Japanese word “ [symbol] ,” each kanji character is 3 bytes, that is, “ [symbol] ” is “ [symbol] : 1/3,” “ [symbol] : 2/3,” “ [symbol] : 3/3,” and for “ [symbol] ,” “ [symbol] : 1/3,” “ [symbol] : 2/3,” “ [symbol] : 3/3,” so the character code is 6 bytes in total.

### (Comparison Data Generation Circuit of Command Generation Circuit)

Then, the comparison data generation circuit 123 of the command generation circuit 127 is, as shown in FIG. 2, configured to break down the above search keyword 125 byte by byte, that is, 8-bit data by 8-bit data (each bit is 0 or 1), generate the comparison data 123 for each 1 byte, and provide it to the character detection circuits 105.

Specifically, in synchronization with the system clock 131 signal generated by the system clock generation circuit 131, 1-byte character codes are sequentially taken out from the beginning or end of the search keyword 125, and given as comparison data 123 to the character detection circuits 105.

Note that, as will be described below, when generating the comparison data 123, this comparison data generation circuit 123 performs processing such as ignoring special characters (wildcard symbols “?”, gap (hereafter also expressed as “Gap”) operators “*”, etc.) included in the search keywords 125 depending on the special characters, replacing the special characters with predetermined character codes, and/or the like.

As will be discussed in detail below, for example, if the search keyword 125 contains a specific wildcard (e.g. “?”), the process of masking (hereafter referred to as “Mask” or “ignore”) the characters corresponding to this wildcard is performed. Such processing according to special character codes is not illustrated here, but for example, it is possible to use a special character lookup table to distinguish between normal characters and special characters.

In addition, this comparison data generation circuit 123 is configured to count the number of bytes in the character string constituting the search keyword 125, and pass the result to the above tournament operation conditions generation circuit 129. (Shift clock generation circuit of command generation circuit)

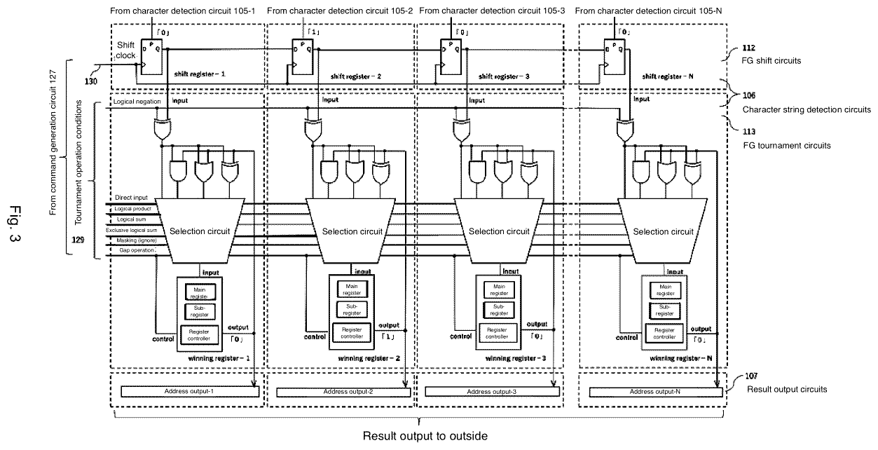

Next, the shift clock generation circuit 130 generates a shift clock 130, which determines the timing for providing specific operation conditions for character string detection to the character string detection circuits 106. Specifically, this shift clock generation circuit 130 is a circuit that provides FG (flag) shift circuits 112 of the character string detection circuits 106 shown in FIG. 3 with a shift clock 130 signal that indicates a predetermined shift timing in synchronization with the aforementioned system clock 131.

Specifically, when the search keyword 125 is 6-byte long, the number of shifts given to the FG shift circuits 112 is 5 times, i.e., 6−(minus) 1, for the case of 6 bytes. This is also the case when the search keyword 125 includes special characters such as wildcard symbols and/or gap operators.

Also, this shift clock generation circuit 130 is configured to determine the timing for providing the operation conditions to the tournament operation conditions generation circuit 129.

### (Tournament Operation Conditions Generation Circuit of Command Generation Circuit)

The tournament operation conditions generation circuit 129 provides the operation conditions to the character string detection circuits 106 in coordination with the shift clock generation circuit 130 described above.

Specifically, predetermined tournament operation conditions 129 are given to FG tournament circuits 113 of the character string detection circuits 106 shown in FIG. 3 after those tournament operation conditions 129 are selected from “direct input,” “logical product,” “logical sum,” “exclusive logical sum,” “mask (ignore),” “gap operation,” “logical negation,” and the like.

As will be discussed in detail below, for example, if the search keyword is 6-byte long and consists of normal characters which do not include special characters such as wildcards, the “direct input” operation command is selected at the time of character detection (first step (Step 1)), and the “logical product” operation command is selected at the time of character string search (Step 5 to Step 11) to be given to the FG tournament circuits 113.

This selection of operation conditions may be determined by, for example, referring to a look-up table.

### (Full-Text Search Circuit)

Next, the full-text search circuits 103 will be described below.

### (Character Storage Elements of Full-Text Search Circuit)

First, the character storage elements 102 of these full-text search circuits 103 are, registers or memories like flip-flops for temporarily storing character text data 132, given from the HOST through the input/output interface 115, in units of 8 bits, i.e., 1 byte, and the character storage elements 102 are configured to store N items of 1 byte data from address 1 to address N.

Here, character text data 132 refers to all kinds of text data, such as WEB text data, text data from novels, magazines, and/or academic papers, patent document text data, internal company document text data, as well as text data from PC and smartphone emails, Word, Excel, and the like.

These character text data 132 items are in various sizes, from a few bytes to several hundred thousand bytes or more per item.

Moreover, these character text data 132 items are composed of a large number of document data (text data), such as from a few items to several tens of billions of items.

This embodiment is, as described above, configured to store in the character storage elements 102 a portion of the character text data 132 of various sizes, for example, 32 KB of character text data 132, from address 1 to address N, and perform full-text search on the stored character text data 132.

FIG. 2 shows, as an example, where a character string “est . . . ” after “y” of the character string “yesterday” is stored in character storage elements 102, In this case, if an address 1 of an address 126 is “e,” an address 2 is “s,” an address 3 is “t” . . . , and an address N is “h,” their UTF-8 character codes are stored in the character storage elements 102 as “01100101” for address 1, “01110011” for address 2, “01110100” for address 3, and “01110100” for address N.

### (Character Detection Circuits of Full-Text Search Circuit)

Next, the character detection circuits 105 of the full-text search circuits 103 are, as shown in FIG. 2, each constituted with a 1-bit match detection circuit 109 connected to the comparison data generation circuit 123 of the command generation circuit 127, and an 8-input logical product circuit 110 connected to the respective 1-bit match detection circuit 109.

### (1-Bit Match Detection Circuits of Character Detection Circuit)

The 1-bit match detection circuits 109 are, as shown in FIG. 2, provided for respective 1-bytes, i.e., the respective 8 memory cells constituting the character storage elements 102, wherein one input is connected to each memory cell, and the other input is connected to each of the 1-byte, or 8-bit, data received as the comparison data 123. And it is configured to perform bit-by-bit match detection operations on both inputs and output the results to the 8-input logic product circuit 110.

Therefore, each 1-bit match detection circuit 109 consists of N×8 match circuits connected in parallel, and performs N parallel operations on N-byte character text data 132.

### (8-Input Logical Product Circuits of Character Detection Circuit)

The 8-input logical product circuit 110 is provided for each 1 byte, and receives output from the 1-byte, or 8 of 1-bit match detection circuit 109, performs a logical product operation on these, and outputs the result.

Therefore, by these 1-bit match detection circuits 109 and 8-input logical product circuits 110, the comparison between the 1-byte comparison data 123 given by the command generation circuit 127 and the N-byte character text data 132 is performed in parallel across all bytes.

In the example shown in FIG. 2, a flag (FG) indicating a match of 8-bit data is output as “1” from the 8-input logical product circuit 110 corresponding to the address 2 of the addresses 126 of a matching full-text search circuit, and “0” is output for mismatched addresses. Note that, in this embodiment, character detection is performed based on the match detection, but it can also be achieved by a combination of a mismatch detection circuit (XOR), an 8-input logical sum (OR) circuit 111, a logical negation (NOT) circuit, and other circuits.

### (Character String Detection Circuits of Full-Text Search Circuit)

Next, the character string detection circuits 106 will be discussed below with reference to FIG. 3.

The character string detection circuits 106 are each composed of the FG shift circuit 112 and the FG tournament circuit 113.

### (FG Shift Circuit of Character String Detection Circuit)

First, the FG shift circuits 112 are respectively configured with N shift registers with preset functions according to the number of the 8-input logic product circuits 110.

In this example, the output of the 8-input logic product circuit 110 is connected to a preset input “P” of the FG shift circuit 112. Data output “Q” of a shift register at an address 1 is connected to data input “D” of a shift register at an address 2, and data output “D” of the shift register at the address 2 is connected to a data input “Q” of a shift register at an address 3.

Similarly, shift registers are connected up to an Nth shift register, and each shift register is connected to the shift clock 130 provided by the command generation circuit 127.

With such a configuration, after a character or character part (1-byte code) that matches the search keyword 125 is detected as a match flag (FG) in the character text data 132 by the character detection circuits 105, the position of this flag is shifted in order n−1 times, where n is the number of bytes of the character string of the search keyword 125 (corresponding to the number of shift clocks), to thereby enable detection of the position of the flag that is continuous for the number of bytes of the search keyword 125, that is, a character sequence 122 (character string), in the FG tournament circuits 113 described next.

### (FG Tournament Circuits of Character String Detection Circuit)

The FG tournament circuits 113 are, as shown in FIG. 3, N circuits that correspond to the FG shift circuits 112, and each FG tournament circuit 113 is configured with a logical circuit group (or an element) capable of performing operations of logical negation, direct input, logical product, logical sum, exclusive logical sum, masking, and gap operation; a select circuit for selecting the operation conditions; and a tournament register for storing the operation results.

With such a configuration, as will be described in detail below, it is possible to detect from the data of the match flag stored in the FG shift circuit 112, the first flag position of n consecutive flags for the number of bytes of the search keyword 125.

Note that the input for the operation conditions of the selection circuit is connected to the tournament operation conditions generation circuit 129 of the command generation circuit 127, and which operation conditions are to be used of the logical negation, direct input, logical product, logical sum, exclusive logical sum, masking (ignore), and gap operation is determined by the tournament operation conditions generation circuit 129 of the command generation circuit 127.

In other words, as described above, the tournament operation conditions 129 determine the operation conditions in the character string detection circuits 106 based on the character string and character type specified as the search keyword 125 to thereby, as will be described in detail later, cause the tournament operation processing to perform the tournament operation processing according to the character string contained in the search keyword 125, and the tournament operation result is stored in the tournament register as FG each time the tournament operation is performed.

In a standard case, a final tournament FG is stored in the tournament register as a logical “1” for the tournament register that survives n×2−1 times of the tournament operations for the character string of the search keyword 125, and “0” for others. (Result output circuits for full-text search circuit)

The result output circuits 107 are, as shown in FIG. 3, N circuits provided corresponding to the N circuits of the FG tournament circuit 113, and are circuits configured to output the operation results of “1” or “0” of the tournament register of the FG tournament circuits 113. Other than a configuration for outputting “1”s and “0”s of all addresses, a configuration for only outputting the addresses whose tournament registers are “1,” and/or as will be described below, a configuration for outputting “there is an operation result” if there is at least one “1” in the N operation results, and “there is no operation result” if there is no “1” in the N operation results, in other words, only outputting a “presence/absence” result may be possible.

The output from this result output circuit 107 as an operation result is, as shown in FIG. 1, configured to be returned to the HOST via the input/output interface 115.

### (Operations of Full-Text Search Processor)

The above configuration will be discussed in more detail below in reference with the operations of this device.

### (Text Data Storage Operation)

First, character text data 132 to be searched for is stored in the character storage elements 102.

At this time, the character text data 132 is transferred via the input/output interface 115 from a CPU of the HOST to the character storage elements 102 directly or by DMA (Direct Memory Access) scheme, and N bytes of character codes are stored.

For most ASCII English texts, all of their character codes may be expressed with a single byte, so N characters will be stored in the character storage elements 102.

On the other hand, in the case of Shift-JIS Japanese texts, a code representing a single character may be expressed using two bytes, so N/2 character will be stored in each character storage element 102.

In addition, since many of the characters in UTF-8 Japanese texts may be expressed using codes that represent a single character with 3 bytes, N/3 character will be stored in each character storage element 102.

Note that it is also possible to store a mixture of the above multiple types of character codes in the character storage elements 102.

### (Character Detection Operation)

Next, a character detection operation is performed based on the search keyword 125 provided by the HOST, and subsequently, a character string detection is performed.

In the character detection operation, character detection is performed based on the comparison data 123 provided from the command generation circuit 127.

The character detection circuit 105 is composed of eight 1-bit match detection circuits 109 per 1 byte, connected to the output of each memory cell of the character storage elements 102, and one 8-input logical product (AND) circuit 110 per 1 byte, connected to the output of the eight 1-bit match detection circuits 109, and therefore, if the character code of a specified comparison data 123 and the character code of the character storage element 102 match (coincide), the output of the logical product circuit 110 at an address 126 of the target full-text search circuit becomes a logical “1.”

The example in FIG. 2 illustrates that the comparison data 123 given from the command generation circuit 127 as “s”: “01110011” and the second address of the address 126 of the full-text search circuit match at all eight of the 1-bit match detection circuits 109, and the AND condition of the logical product circuit 110 is satisfied (8-bit match).

This result is stored as a logical “1” FG (flag) in the FG shift circuit 112, which will be described below, as a character detection result for each byte, and since the other addresses of the address 126 of the full-text search circuit do not match, a logical “0” is stored as a character mismatch in those FG shift circuits 112.

### (Character String Detection Operation)

Next, the character string detection operation is performed based on the results of the above character detection.

At this time, the character string detection is performed based on commands of the shift clock 130 and the tournament operation conditions 129 provided by the command generation circuit 127.

As described above, the character string detection circuit 106 is constituted with the FG shift circuits 112 and the FG tournament circuits 113.

The FG shift circuits 112 has functions for storing and data-shifting the match results of the parallel character match detections by the character detection circuits 105, for example, character match results (FG) such as “s,” “e,” “a,” “r,” “c,” “h,” and “ [symbol] : 1/3,” “ [symbol] : 2/3,” “ [symbol] : 3/3,” “ [symbol] : 1/3,” “ [symbol] : 2/3,” “ [symbol] : 3/3” described above.

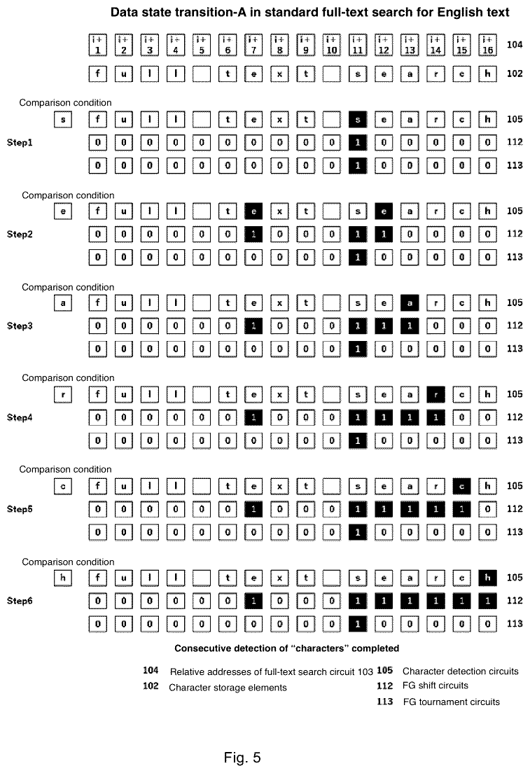

The FG shift circuits 112 store and shift the data of N of FGs in fully parallel (N-parallel) manner preset from the output of the character detection circuits 105 every time the shift clock 130 for shift operation is provided from the command generation circuit 127. (Specific examples of this data shift will be discussed below in reference with FIG. 5 to FIG. 12.)

Whereas, the FG tournament circuits 113 have functionality to determine whether or not the detected character sequences “s,” “e,” “a,” “r,” “c,” “h,” or “ [symbol] : 1/3,” “ [symbol] : 2/3,” “ [symbol] : 3/3,” “ [symbol] : 1/3,” “ [symbol] : 2/3,” “ [symbol] : 3/3,” etc. match the character sequence 122 (character string) given as the search keyword 125 (whether or not the character sequence is valid), and detect the address 126 of the full-text search circuit corresponding to the starting or ending address of the character string of the search keyword 125.

These FG tournament circuits 113 are each configured with logic elements such as logical product and logical sum as well as exclusive logical sum and logical negation for advanced tournament operations, a selection circuit for selecting the logical operations of the above logic elements, and a tournament register for storing the operation results output from the selection circuit.

The selection circuit is input with selection signals for the operation conditions, logical negation, logical product, logical sum, exclusive logical sum, masking (ignore), and gap operation, which are provided by the tournament operation condition generation circuit 129 of the command generation circuit 127.

In the present embodiment, the tournament register is composed of two registers: a tournament main register and a tournament sub-register for retaining the intermediate results of the tournament operations, for the purpose of improving the convenience and performance of the operation, and which of these registers is used or the like is controlled by the command generation circuit 127.

As an example, the present embodiment is configured so that for normal operations, the tournament main register is used, and for special operations such as gap operation, both the tournament main register and the tournament sub-register may be operated.

Therefore, when simply referring to a tournament register, it means the tournament main register, and in the case of gap operation, the main and sub registers are described separately.

Notably, since this circuit configuration shows the concept of tournament operations, it shows conceptual content such as the configuration of logic circuits and registers, and is not limited to this configuration.

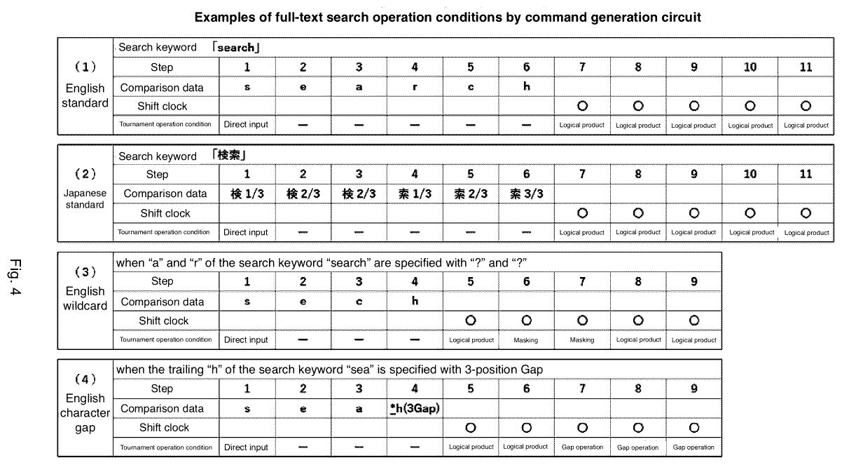

Specific tournament operations are described below in reference with FIG. 4 and later, but general content of the tournament operations are as follows.

That is, as the first step in detecting a character string, when direct input is selected in the tournament operation conditions 129, the input received from the output of the FG shift circuit 112 is directly entered to the tournament register of the FG tournament circuit 113.

In the case of this example, the above operations result in logical “1” for the second address of the addresses 126 of the full-text search circuit, and logical “0” for the other addresses.

As a subsequent step, if the logical product is selected in the tournament operation conditions 129 in synchronization with the one shift clock 130 for shift operations given by the command generation circuit 127, a first (initial) tournament operation is executed by performing a logical product operation on the output of the tournament register and the input received from the FG shift circuit 112.

As a result of a predetermined number of clock shifts 130 and the tournament operations, the tournament register output of the FG tournament circuit 113 at the address 126 of tournament winners of the full-text search circuit will be a logical “1,” and the other register outputs will be a logical “0.”

If “search” is the search keyword 125, the address 126 of the tournament winner of the full-text search circuit has a character code stored corresponding to the first address “s” of the character string of the search keyword 125 to be searched.

If the keyword “search” is detected backward from the end as in “hcraes,” the end address “h” will be detected.

The above is an operation overview of detecting a common character sequence 122 (character string).

Specific examples of full-text search will be discussed in detail in reference with FIG. 4 as well as FIG. 5 to FIG. 12.

### (Result Output Operations)

The result output circuits 107 have functionality for outputting the output of the FG tournament circuits 113 which had a character sequence 122 (character string) with a predetermined number of characters, to the HOST as a logical “1,” and the others as logical “0.”

Logical states of the above FG tournament circuits 113 are output from the result output circuit 107 of the full-text search operations via the input/output interface 115 to the HOST.

The method for outputting the result may be any method, such as outputting the logical state of all addresses or outputting the numbers (addresses) of the addresses of tournament winners.

As described above, in this full-text search processor 101, the N full-text search circuits 103, each composed of the character storage element 102 as well as the character detection circuit 105 and the character string detection circuit 106, perform full-text search operations at N degree of parallelism, wherein to thereby achieve advanced, efficient, and high-speed full-text search.

Since the above configuration may be implemented using only general-purpose logic, it may be easily realized using an ASIC (Application Specific Integrated Circuit), needless to say, and also an FPGA (Field Programmable Gate Array). Details will be described below.

### (Command Generation Operations)

Next, referring to FIG. 4, we will discuss the command generation operations, that is, the full-text search operation condition generation operations, performed by the command generation circuit 127.

The command generation circuit 127, as described above, generates a predetermined command based on the search keyword 125 provided by the HOST.

The command generation circuit 127 has functionality for generating full-text search commands based on various search conditions, including not only search keywords 125 such as “search,” but also search keywords 125 which include wildcards and character gap (character position tolerance).

In this example, four types of commands (instructions) are shown as representative examples: (1) (full-text search for) English Standard, (2) (full-text search for) Japanese Standard, (3) (full-text search for) English Wildcard, and (4) (full-text search for) English Character Gap.

The first line of each table shows the operation steps (order) of the full-text search, and indicates which command (instruction) is given to the full-text search circuits 103 at which step. Here, each step is executed in synchronization with the system clock 131.

In the second line, “comparison data” 123 shows comparison data given to the character detection circuits 105, such as “s,” “e,” “a,” “r,” “c,” “h,” and/or “ [symbol] : 1/3,” “ [symbol] : 2/3,” “ [symbol] : 3/3,” “ [symbol] : 1/3,” “ [symbol] : 2/3,” “ [symbol] : 3/3.”

In the third line, the “shift clock” 130 indicates the clock feed given from the shift clock generation circuit 130 to the FG shift circuits 112, indicated by a “o” mark. For example, in an example of “(1) English standard,” the comparison data is given in the first six steps, and the shift operation will be executed by the FG shift circuits 112 in the next Steps 7 to 11.

In the fourth line, the “tournament operation conditions” 129 indicate the tournament operation conditions to be given to the FG tournament circuits 113, such as “direct input,” “logical product,” “masking (Mask, ignore),” “gap (Gap) operation,” and the like.

In FIG. 4, (1) full-text searches for English standard, and (2) full-text searches for Japanese standard, show standard full-text search examples. In this example, full-text search command examples (all for 6-byte) are shown with 6 of 1-byte characters, “search” for English, and 2 of 3-byte characters, “ [symbol] ” for Japanese (6 bytes for both cases).

On the other hand, in the case of the English wildcard in (3), the “a” and “r” in “search” are specified as wildcards “?”, “?”, and in this case, the comparison data 123, the shift clock 130, and the tournament operation conditions 129 are as shown in FIG. 4. In this case, the wildcard indicated by the special character “?” is ignored as the comparison data 123 according to the lookup table reference, and subsequently, the shift operation for 6 bytes is executed, so the total number of steps is less than the number of steps for the normal search in (1) and (2) above (11 steps in this example) by the number of wildcard characters (2 characters in this example) (9 steps in this example).

The full-text search in the case of the English character gap in (4) is a command example, where the character “h” is at any of the three positions after “s,” “e,” and “a,” for example, wherein an operation condition “*h” 3Gap using a special character and indicating the range of positions is used to match any of “seah,” “sea*h,” or “sea**h.”

As discussed above, in this example, the command generation circuit 127 is described to be provided inside the full-text search processor 101, but commands may be sent by software processing from the CPU of the HOST to the full-text search processor 101 step by step, or may be sent all at once.

The following shows the contents of the full-text search operations for the full-text search for English standard, the full-text search for Japanese standard, the full-text search for English wildcard, and the full-text search English character gap.

### (Standard Full-Text Search Operations for English)

FIG. 5 illustrates data state transition-A (character detection process) in standard full-text search for English text.

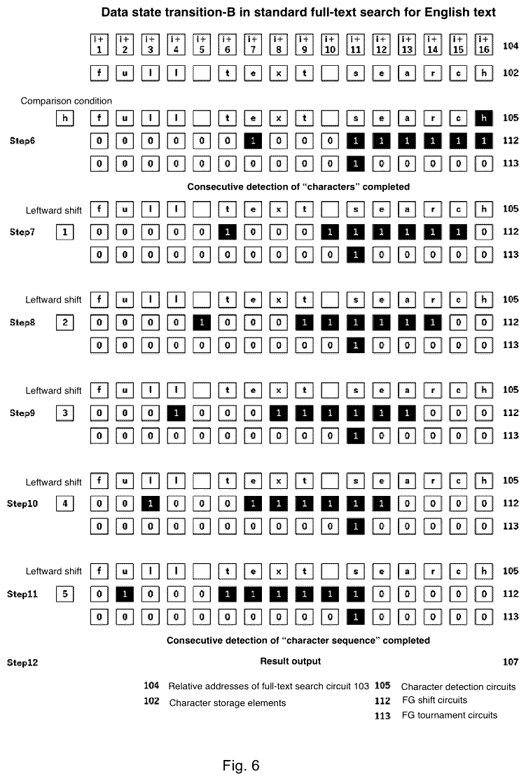

FIG. 6 illustrates data state transition-B (character string detection process) in standard full-text search for English text.

The following is described under assumption that the commands introduced in (1) of FIG. 4 are given to the full-text search circuits 103 sequentially in steps, and based on these commands, the full-text search circuits 103 perform full-text search processing.

In the present embodiment, the data state transitions for each component of 16 (16 addresses of) full-text search circuits 103 that make up part of the N (N addresses of) full-text search circuits 103.

In the present embodiment, 16-character English text data “full text search” in UTF-8 character code is stored from an i+1th byte (hereinafter, simply referred to as “relative 1st address”) to an i+16th byte (hereinafter, simply referred to as “relative 16th address”) of a relative address 104 of the full-text search circuits of the character storage element 102 in 16 bytes, in the character storage elements 102 of the full-text search circuit 101.

This is an embodiment in which a full-text search is performed for this character text data 132, using six characters of “search” as a search keyword 125 with a byte count n of 6 (6-byte long).

Although it is omitted in FIGS. 5 to 12, in an initial state of Step 0, all FG shift circuits 112 and FG tournament circuits 113 are cleared with a logical “0” state.

The processes from Step 1 to Step 11 are controlled by the full-text search circuits 103 according to the commands (comparison data 123, shift clock 130, and tournament operation conditions 129) given by the command generation circuit 127.

Step 1 to Step 6 shown in FIG. 5 correspond to Step 1 to Step 6 in (1) of FIG. 4, and indicate the processing steps for detecting the characters “search” from the stored character text data 132 of “full text search.”

The part to be noted is shown with the character inverted black and white.

In Step 1, the character “s,” composed of a single byte, is detected, and in the present embodiment, the character detection circuit 105 at the relative 11th address detects “s.”

The detected FG is preset to the FG shift circuit 112, and the FG shift circuit 112 at the relative 11th address becomes logical “1,” and the others become logical “0.” Further, since this FG is the first-round tournament FG, the “direct input” is selected as the operation condition for the FG tournament circuit 113, the FG tournament circuit 113 (register) at relative 11th address is set to logical value “1.”

In Step 2, the character “e,” composed of a single byte, is detected, and in the present embodiment, the character detection circuits 105 at the relative 7th address and the relative 12th address detect “e.”

The detected FGs are set in the FG shift circuits 112. At this time, as shown in FIG. 4 (1), no operation condition is given to the FG tournament circuits 113, and the corresponding tournament circuits remain set to the logical value “0.”

Step 3 to Step 5 are omitted because similar operations are repeated to those in Step 2.

In the last Step 6, the character “h,” composed of a single byte, is detected, and in the present embodiment, the character detection circuit 105 at the relative 16th address detects “h.”

As the detected FG, the logical value “1” is set in the FG shift circuit 112.

In this example, all of the characters of the given search keyword 125 “search” were detected consecutively from relative 11th address in six steps, which number is the same as the number of bytes of the character string of the given comparison data 123.

It should be noted that, in Step 6, there are consecutive six FGs “1111111” from the relative 11th address to the relative 16th address of the FG shift circuit 112, and the FG at the relative 11th address of the FG tournament circuit 113 set in Step 1 is “1.”

FIG. 6 shows the data state transition-B (consecutive detection of a character sequence) from Step 6 onwards.

Step 6 in FIG. 6 is the same as the final result of the character detection described previously.

Step 7 to Step 11 correspond to (1) in FIG. 4, and show the “character string detection” processes for detecting the character string 122 (character string) of “search” detected in Steps 1 to 6 above.

In Step 7, one clock signal is given to the FG shift circuits 112 from the shift clock generation circuit 130 to thereby shift the FGs of the FG shift circuits 112 shown in Step 6, to left by one byte, and logical product (AND) operation is performed with the FG of the FG tournament circuits 113 by making the operation condition for the shifted FGs and the FG tournament circuits 113 a “logical product” (see FIG. 4 (1)).

In this step, since the FGs in the FG tournament circuits 113 and at the relative 11th address of the FG shift circuits 112 exist, to satisfy the AND condition, the relative 11th address in the FG tournament circuits 113 remains as in Step 6 (i.e., survives), in other words, it remains as the logical value “1.”

Step 8 to Step 10 are omitted because similar operations are repeated.

In the final Step 11, the FGs of the FG shift circuits 112 shown in Step 10 are further shifted to the left by one byte (a total of 5 shifts to the left), and the logical product (AND) operation is performed between the shifted FGs and the FG of the FG tournament circuit 113.

In this step, since the FGs exist at the relative 11th address of both the FG tournament circuits 113 and the FG shift circuits 112 to satisfy the AND condition, the relative 11th address in the FG tournament circuits 113 remains as in Step 10 (remains as the logical value “1”), and it becomes a tournament survivor.

As above, the shift operations and the logical product (AND) tournament operations are repeated by n−1 times=6−1=5 times, where n is the byte count of the character string of the given comparison data 123, and the relative 11th address that wins through to the end becomes the final tournament winner FG.

The above processes consecutively detected that the character sequence 122 (character string) from the relative 11th address to the relative 16th address is the same as the character sequence 122 (character string) of the given search keyword 125 condition.

The above described the operation content in the illustrated range, but in actual processing, it means that a character string that matches (is identical with) the character sequence 122 (character string) of the given search keyword 125 condition has been consecutively detected in the character sequence 122 (character string) from the 1st address to the Nth address of the character storage elements 102.

In this scheme, as described above, only the case where all the detected characters are consecutive becomes the final tournament winner FG, and therefore, although the two “e” characters are detected at the relative 7th address and the relative 11th address in Step 2, the “e” at the relative 7th address is processed as noise because the character sequence 122 (character string) is not formed.

By outputting this operation result from the result output circuits 107 to the HOST in Step 12, the HOST is enabled to know whether or not the character string “search” exists in the target character text data 132 between the 1st address and the Nth address, and at which position the first address of the search keyword 125 character string exists.

As will be described below, it is particularly important to be able to detect the character sequence 122 (character string) by consecutively detecting characters in the same number of steps as the number of bytes n of the character string of the given comparison data 123, and by consecutively repeating the shift operations and the logical product (AND) operations n−1 times, where n is the number of bytes of the character string of the given comparison data 123.

In the detection of the character string of the given search keyword 125, it is not necessary to detect the search keyword 125 character string from the beginning, as in “search”, and backward detection from the end, as in “hcraes” may be possible.

In that case, it is sufficient to make the shift operation of the shift register rightwards, and detect the last address “h.”

Such a shift operation may be easily achieved by using reversible shift registers (shift registers capable of forward/backward shifting).

### (Standard Full-Text Search Operations for Japanese)

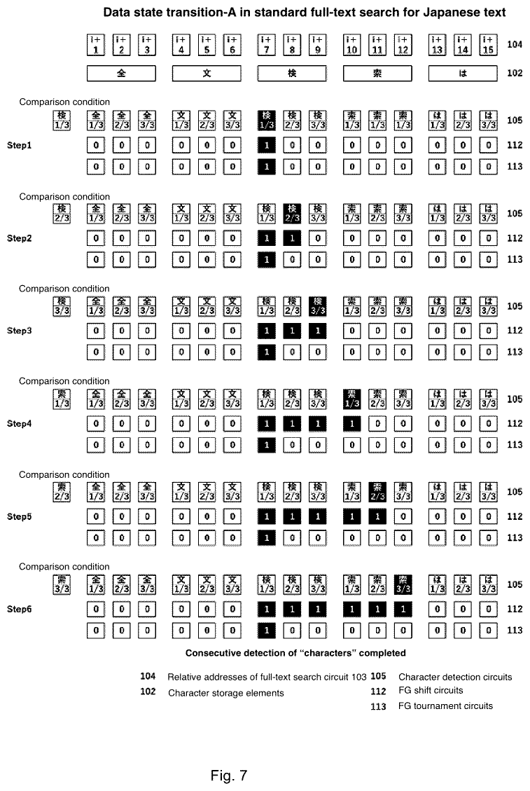

FIG. 7 illustrates data state transition-A (character detection process) in standard full-text search for Japanese text.

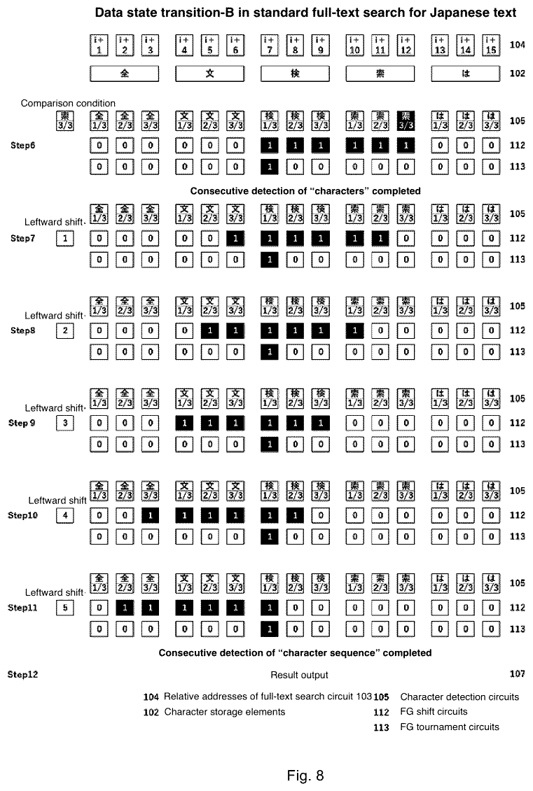

FIG. 8 illustrates data state transition-B (character string detection process) in standard full-text search for Japanese text.

The commands shown in (2) of FIG. 4 (the comparison data 123, the shift clock 130, and the tournament operation conditions 129) are given to the full-text search circuits 103 sequentially in steps, and based on these commands, the full-text search circuits 103 perform full-text search processing.

In the present embodiment, the data state transitions for each component of 15 full-text search circuits 103 that make up part of the N full-text search circuits 103.

As shown in FIG. 7, in the present embodiment, 5-character Japanese text data “ [symbol] ” in UTF-8 character code is stored from an i+1th byte (hereinafter, simply referred to as “relative 1st address”) to an i+15th byte (hereinafter, simply referred to as “relative 15th address”) of a relative address 104 of the full-text search circuits of the character storage element 102 in 15 bytes, in the character storage elements 102 of the full-text search circuit 101.

This is an embodiment in which a full-text search is performed using the two characters “ [symbol] ” from the above character code as a search keyword 125 with a byte count n of 6.

As with the previous description, in the processes from Step 1 to Step 11, the full-text search circuit 103 performs full-text search according to the commands given by the command generation circuit 127.

Step 1 to Step 6 indicate the processing for detecting the characters “ [symbol] ” and “ [symbol] ” from the stored character text data 132 of “ [symbol] .”

The part to be noted is shown with the character inverted black and white.

In Step 1, the first byte of the character code of the 3-byte character “ [symbol] ,” i.e., “ [symbol] : 1/3” is detected, and in the present embodiment, the character detection circuit 105 at a relative 7th address detects “ [symbol] : 1/3.”

The detected FG is preset in the FG shift circuit 112 as discussed previously. Further, this FG is set in the FG tournament circuit 113 as an initial tournament winner FG as described above.

Step 2 to Step 5 are omitted because similar operation contents are repeated.

In the last Step 6, the third 1-byte character code “ [symbol] : 3/3” of the 3-byte character “ [symbol] ” is detected, and in the present embodiment, the character detection circuit 105 at a relative 12th address detects “ [symbol] : 3/3.”

The detected FGs are set in the FG shift circuits 112.

As above, in six steps, which number is the same as the number of bytes of the character string of the given comparison data 123, the characters “ [symbol] ” of the given search keyword 125 were detected consecutively.

It should be noted that, in Step 6, there are consecutive six FGs “1111111” from the relative 7th address to the relative 12th address of the FG shift circuit 112, and the FG at the relative 7th address of the FG tournament circuit 113 set in Step 1 is “1.”

FIG. 8 illustrates data state transition-B (character string detection process) in standard full-text search for Japanese text.

Step 6 is the final result of the character detection described previously.

Step 7 to Step 11 illustrate the processing for detecting the character sequence 122 (character string) of “ [symbol] ” detected as above.

In Step 7, in a similar fashion to the previous discussion, the FGs of the FG shift circuits 112 shown in Step 6 are shifted to the left by one byte, and the logical product (AND) operation is performed between the shifted FGs and the FG of the FG tournament circuit 113 to show the result.

In this step, since the FGs in the FG tournament circuits 113 and at the relative 7th address and the relative 16th address of the FG shift circuits 112 exist, to satisfy the AND condition, the relative 7th address in the FG tournament circuits 113 remains as in Step 6 (i.e., survives).

Step 8 to Step 10 are omitted because similar operations are repeated.

In the final Step 11, the FGs of the FG shift circuits 112 shown in Step 10 are further shifted to the left by one byte (a total of 5 shifts to the left), and the logical product (AND) operation is performed between the shifted FGs and the FG of the FG tournament circuit 113.

In this step, as discussed previously, since the FGs exist at the relative 7th address of both the FG tournament circuits 113 and the FG shift circuits 112 to satisfy the AND condition, the relative 7th address in the FG tournament circuits 113 remains as in Step 10 and becomes a tournament survivor.

As above, the shift operations and the logical product (AND) tournament operations are repeated by 6 times—which is the same as the byte count n of the character string of the given comparison data 123—minus 1 time=5 times, and the relative 7th address that wins through to the end becomes the final tournament winner FG.

The above processes consecutively detected that the character sequence 122 (character string) from the relative 7th address to the relative 12th address is the same as the character sequence 122 (character string) of the given search keyword 125.

The above described the operation content in the illustrated range, but in actual processing, it means that whether or not a character string exists that matches (is identical with) the character sequence 122 (character string) of the given search keyword 125 in the character sequence 122 (character string) from the 1st address to the Nth address of the character storage elements 102 has been consecutively detected.

By outputting this operation result from the full-text search processor 101 to the HOST in Step 101, the HOST is enabled to know whether or not the character string “ [symbol] ” exists in the target character text data 132 between the 1st address and the Nth address, and at which position (address) the first address of the character string exists.

As in the standard full-text search for English text described above, it is particularly important to be able to detect the character sequence 122 (character string) by consecutively detecting characters in the same number of steps as the number of bytes n of the given comparison data 123, and by consecutively repeating the shift operations and the logical product (AND) operations n−1 times, where n is the number of bytes of the given comparison data 123.

The above are only two examples for English and Japanese text, but it has been shown that, by using standard character codes such as UTF-8, the present full-text search may be performed commonly for all languages worldwide.

Next, we will show an application example that uses wildcard function and gap function, which are essential for advanced fuzzy full-text search.

(Full-Text Search Operations when Wildcards are Applied)

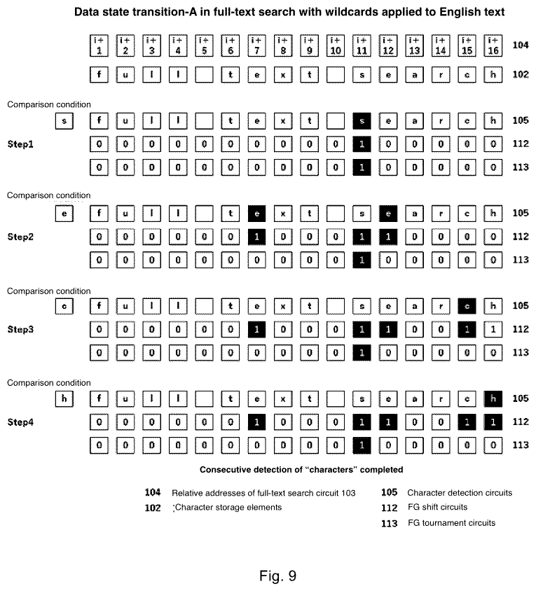

FIG. 9 illustrates data state transition-A (character detection process) in full-text search when wildcards are applied to English text.

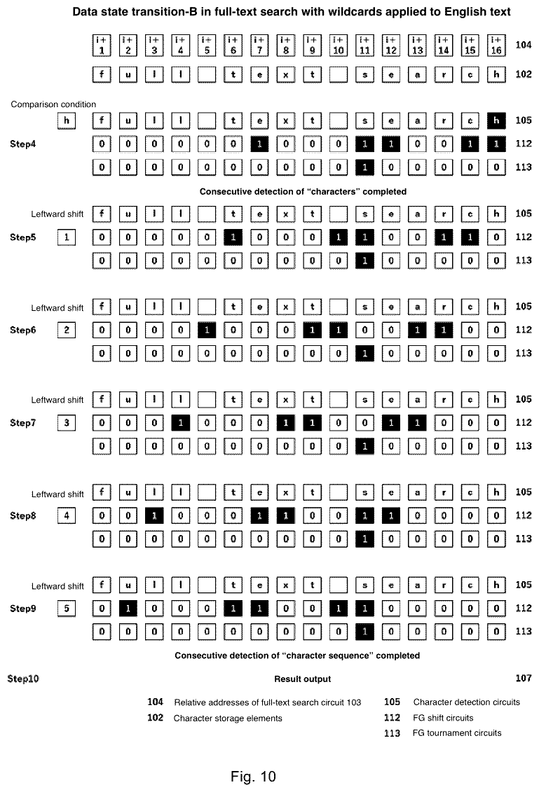

FIG. 10 illustrates data state transition-B (character string detection process) in full-text search when wildcards are applied to English text.

In the following description, the commands shown in (3) of FIG. 4 (the comparison data 123, the shift clock 130, and the tournament operation conditions 129) are given to the full-text search circuits 103 sequentially in steps, and based on these commands, the full-text search circuits 103 perform full-text search processing.

A wildcard is used when the spelling is uncertain, or the like.

This example shows the case where the wildcard “?” is applied to the third and fourth characters of the “search” string.

Step 1 and Step 2 of the character detection are as previously described.

When the special character “?” is applied to the third and fourth characters, the command generation circuit 127 does not provide the comparison data 123 to the full-text search circuits 103; these third and fourth characters are skipped; and the character detection process is not executed for them.

Therefore, the character “c” is detected in Step 3 and the character “h” is detected in Step 4.

The character detection is complete in the above four steps, and it is regarded that the required characters are detected consecutively.

FIG. 10 illustrates data state transition-B (character string detection process) in full-text search when wildcards are applied to English text.

Step 4 is the final result of the character detection described previously.

Steps 5 to 9 are the character detection steps. In this case, since the search keyword 125, including the above wildcard, is 6 bytes, the character detection process is executed 6-1 times, i.e., in 5 steps (Steps 5 to 9).

However, for Steps 6 and 7, where wildcards are specified, “masking (ignore)” is selected as the operation condition generated by the tournament operation conditions generation circuit 129 of the command generation circuit 127 and given to the FG tournament circuits 113. This causes the operation of the FG tournament circuits 113 to be ignored and keeps the logical state of the FG tournament circuit 113 unchanged.

In other words, since Step 5 is not subject to the wildcard, the operation of FG tournament circuits 113 is the AND operation as previously discussed.

Then, since Step 6 and Step 7 are steps subject to wildcard operation, the AND operation of the FG tournament circuits 113 is masked (ignored), and the FG tournament circuits 113 are kept as a tournament survivor through Step 6 and Step 7 to proceed to Step 8.

Since Step 8 and Step 9 are not subject to wildcard operation, normal AND operations are performed, and the “s” in the relative 11th address survives the tournament in the final Step 11.

The above processes consecutively detected that the character sequence 122 (character string) from the relative 11th address to the relative 16th address matches (is identical with) the character sequence 122 (character string) of the given search keyword 125.

The above described the operation content in the illustrated range, but in actual processing, it means that a character string that matches (is identical with) the character sequence 122 (character string) of the given keyword condition has been consecutively detected in the character sequence 122 (character string) from the 1st address to the Nth address of the character storage elements 102.

This example showed the case where wildcards were specified in the middle of a character string, but a wildcard position is not limited to the middle of a character string, but it may be also at any position, such as the beginning or the end.

As described above, the present scheme enables wildcard processing by omitting the processing that wildcards are subject to when characters of the search keyword string 125 contain an externally given wildcard.

(Full-Text Search when Character Gap is Applied)

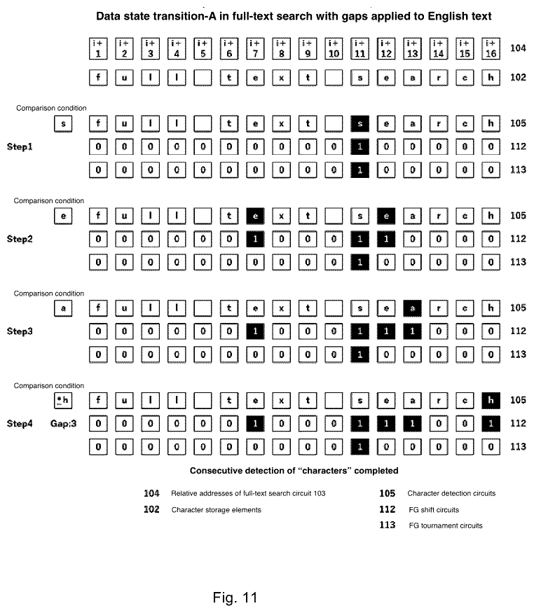

FIG. 11 illustrates data state transition-A (character detection process) in full-text search when character gap is applied to English text.

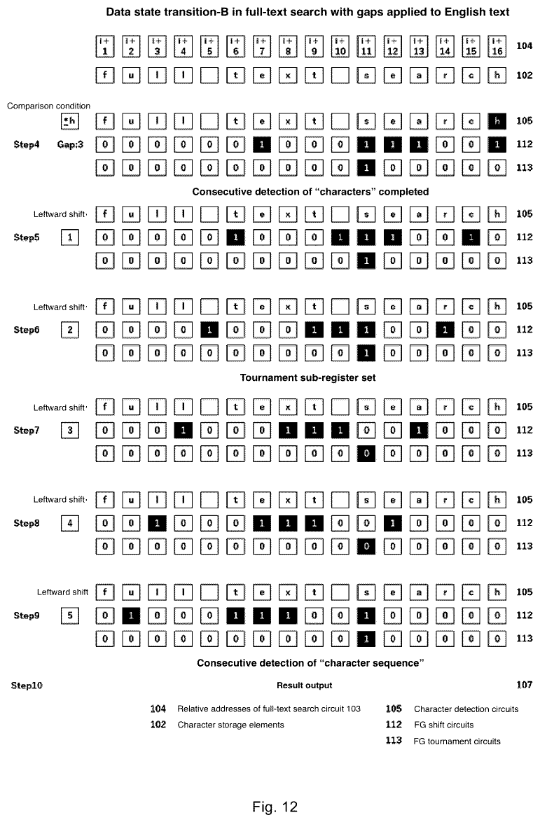

FIG. 12 illustrates data state transition-B (character string detection process) in full-text search when character gap is applied to English text.

The following is described under assumption that the commands introduced in (4) of FIG. 4 are given to the full-text search circuits 103 sequentially in steps, and based on these commands, the full-text search circuits 103 perform full-text search processing.

The character position tolerance (gap) is also used when the spelling is uncertain, or the like.

As described above, the special character “*h” and the character position “3 Gap” indicate the allowable position of the character “h” and, in this example, if it is assumed that “sea” is certain and that there is a character “h” within three places from 0 to 2 (Gap 3), that is, it is an operational method that any of “seah,” “sea*h,” and “sea**h” is regarded a match. Its specific example will be shown below.

The detection of the characters “sea” from Step 1 to Step 3 is as previously described.

In Step 4, Gap 3 is specified to the special characters “*h.”

Since “h” is specified, the FG shift circuit 112 at the relative 16th address is set to a logical “1.”

The character detection is now complete, and it is regarded that the required characters have been detected consecutively.

FIG. 12 likewise shows the data state transition-B in the character string detection process.

Step 4 is the final result of the character detection described previously.

The character string detection Step 5 is the same as the previous cases.

In the case of gap specification, if “h” is detected in any of the Steps 7, 8, or 9, the gap operation is executed to make the FG tournament circuit 113 which is a tournament survivor in Step 6 as the tournament survivor.

The gap operation is performed using the main register and the sub register of the FG tournament register.

Specifically, at Step 6, the tournament sub-register at the relative address that has been winning the tournament up to this point is set to a logical “1.”

Therefore, in this example, the FG tournament sub-register at the relative 11th address is set to a logical “1.”

Step 7 is for searching the character sequence 122 (character string) of “seah.” The tournament sub-register remains at logical “1.”

Since the output of the FG shift circuit 112 at the relative 11th address becomes a logical “0”, and the tournament sub-register is logical “1,” the AND condition is not satisfied and the tournament main register cannot be restored to “1.”

Step 8 is for searching the character sequence 122 (character string) of “sea*h.”

The tournament sub-register remains at logical “1.”

Since the output of the FG shift circuit 112 at the relative 11th address becomes a logical “0”, and the tournament sub-register is logical “1,” the AND condition is not satisfied and the tournament main register cannot be restored to “1” as in the previous step.

Step 9 is for searching the character sequence 122 (character string) of “sea**h.”

The FG tournament sub-register at the relative 11th address is set to a logical “1.”

At this step, the FG shift circuit 112 at the relative 11th address becomes a logical “1.”

Since the AND condition of both is satisfied, the tournament main register is restored to the logical “1.”

If in any of Steps 7, 8, or 9, the AND condition is not satisfied with the FG shift circuit 112 at the relative 11th address with the logical “1” and the tournament sub-register with the logical “1,” the tournament main register at the relative 11th address will not be able to survive the tournament.

In the immediately subsequent Step 10, the operation result is output by the result output circuits 107.

The above operations and output enable the full-text search of character strings that include gaps among characters, such as “seah”, “sea*h”, and “sea**h.”

Although the explanation is omitted, gaps may be set at at any positions by detecting character strings from the back.

The wildcard function and/or the gap function described above allows improvement of the convenience of full-text search operations.

As described above, the present scheme enables gap-tolerant processing when character gaps are tolerated in the character string of an externally given search keyword 125, by incorporating two sets of registers into the tournament circuits.

It is particularly important that the wildcard function and/or the gap function may be processed in a similar number of steps to, or less than, that of the standard full-text search.

In the present embodiment, the special characters for specifying the wildcard function and/or the gap function are indicated with “?” and/or “*,” but the present invention is not limited to this.

The greatest feature of the present scheme is that it is a full-text search operation with the degree of parallelism N, and it is capable of performing advanced full-text searches employing not only the forward match, middle match, and backward match that are essential for the needs of various full-text searches (including keyword searches), but also the wildcard function and gap function for characters.

Since the morphological indexes are not employed, new terms such as popular words may be accommodated in real time as well.

Furthermore, this scheme enables full-text search for any character code as long as the character code is defined in units of integral multiples of a byte (8 bits).

Therefore, this scheme allows standardization of full-text search systems for all languages worldwide.

### Novelty and High Speed of the Algorithm of the Present Embodiment

The novelty and high speed of the algorithm of the present embodiment will be described.

In Patent Document 2, Japanese Patent No. 4588114, “MEMORY HAVING INFORMATION NARROWING DETECTION FUNCTION, METHOD FOR USING THE SAME, AND DEVICE INCLUDING THE MEMORY,” a pattern matching method with a shift register is shown.

It has been confirmed that hardware pattern matching of images according to this method is 10,000 times faster compared to software pattern matching using a conventional CPU.

However, since the pattern matching of this prior invention is mainly intended for image pattern matching, it is necessary to satisfy various matching conditions associated with image processing, and its configuration requires many steps.

Therefore, when detecting a continuous character string of n bytes using conventional schemes, it is required to perform n times of character detection operations and 1+2+3+ . . . (n−1) times of shift operations for character string detection.

In comparison, as shown in FIG. 5 to FIG. 12, the present scheme is capable of performing full-text search pattern matching processing in a total of n×2−1 times, consisting of n times of character detection operations+(n−1) times of shift operations for character string detection.

Therefore, compared to the number of operations in the conventional scheme, for example, in the case of 6 bytes of 2 Japanese characters, the conventional scheme requires 6 (character detection)+15 (5+4+3+2+1) (character string detection)=21 operations, whereas the present scheme requires 6 (character detection)+5 (character string detection)=11 operations, to thereby reduce the number of operations down to 21/11=about ½.

For 12 bytes of 4 Japanese characters, the conventional scheme requires 12 (character detection)+78 (11+10 . . . +2+1) (character string detection)=90 operations, whereas the present scheme requires 12 (character detection)+11 (character string detection)=23 operations, to thereby reduce the number of operations to 90/23=about ¼.

For 24 bytes of 8 Japanese characters, the conventional scheme requires 24 (character detection)+300 (23+22 . . . 2+1) (character string detection)=324 operations, whereas the present scheme requires 24 (character detection)+23 (character string detection)=47 operations, to thereby reduce the number of operations to 324/47=about 1/7.

As described above, the present scheme is particularly advantageous when the character string of the search keyword 125 is long, and the operations including the wildcard function and gap function are also simple and efficient.

Therefore, by using this algorithm, the performance of full-text search may be greatly improved, and a high-speed full-text search system may be realized even without an index.

### (Overall Configuration of Full-Text Search Processor)

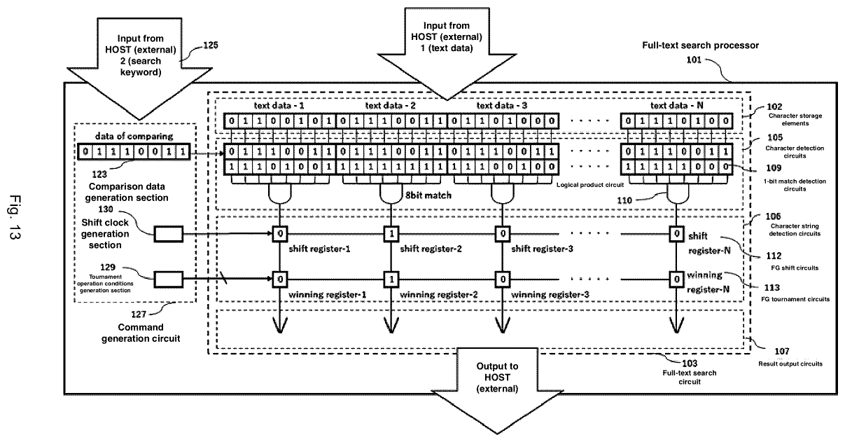

FIG. 13 shows an example of overall configuration of a full-text search processor.

In this example, the character text data 132 indicated with an input 1 from the HOST is transferred through the input/output interface 115 directly from the HOST CPU, or by DMA (Direct Memory Access) scheme, and N bytes of character codes are stored in the character storage elements 102.

The search keyword 125 for the full-text search indicated by an input 2 from the HOST is provided by the HOST via the input/output interface 115.

This search keyword 125 is converted into the full-text search operation conditions 114 by the command generation circuit 127.

One of the full-text search operation conditions 114 is the comparison data 123 created by the comparison data generation circuit 123, and this comparison data 123 is given to the input of the character detection circuits 105.

The other part of the full-text search operation conditions 114 are the shift clock 130 created by the shift clock generation circuit 130 and the tournament operation conditions 129 created by the tournament operation condition generation circuit 129, and these two signals are given to the input of the character string detection circuits.

In this example, the 8-bit data “s”: “01110011” of the comparison data 123 is subject to comparison operations bit by bit as shown previously, and the comparison operation result is shown as the operation result of the 1-bit match detection circuits 109.

At the second address of the address 126 of the full-text search circuits, the operation result of the 1 byte of the 1-bit match detection circuit 109 is “11111111,” so the output of the 8-input logical product circuit 110 becomes a logical “1.”

This operation result indicates that the shift register of the FG shift circuit 112 is set to a logical “1.”

Further, the register of the FG tournament circuit 113 at the second address of the address 126 of the full-text search circuits has survived with a logical “1,” and all addresses other than the second address is set to a logical “0.” Further, the register of the FG tournament circuit 113 at the second address of the address 126 of the full-text search circuits has survived with a logical “1,” and all addresses other than the second address is set to a logical “0.”

The logical states of the above FG tournament circuits 113 are output to the HOST from the result output circuits 107 for the full-text search operations via the input/output interface 115.

The method for outputting the results is as described above.

The method for efficiently outputting the results will be described below.

### Configuration Example of Processor for Performing Refinement Searches and Overall Output

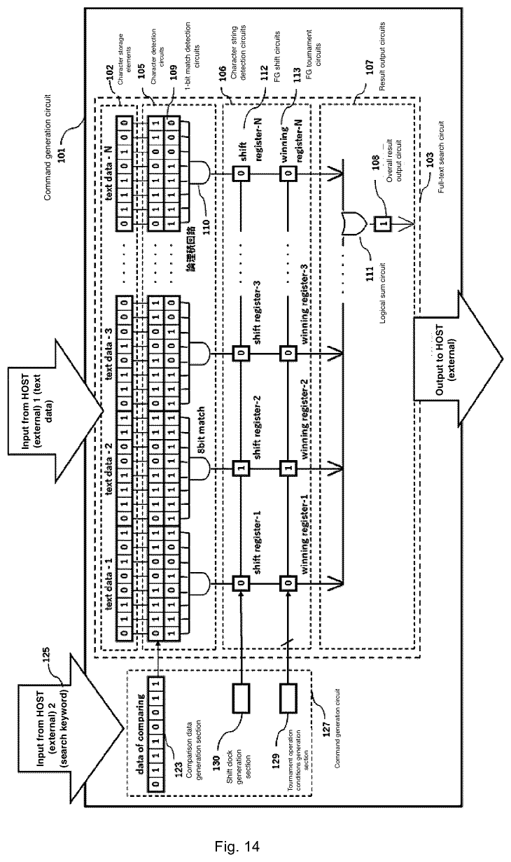

FIG. 14 illustrates a configuration of a full-text search processor when performing refinement searches.

As an example, a block diagram is shown for the case where a refinement search is performed using a plurality of keywords such as “ [symbol] ,” “ [symbol] ,” and “ [symbol] .”

The logical sum (OR) circuit 111 performs a logical sum (OR) operation on outputs of all of the result output circuits 107, and if there is at least one tournament win in any one of them, sets an overall result output circuit 108.

The refinement search operations are as follows.

Initially, if there was a tournament win via a keyword search for “ [symbol] ,” the overall result output circuit 108 is set.

Next, if there was a tournament win via a keyword search for “ [symbol] ,” the overall result output circuit 108 remains set.

After that, if there was a tournament win via a keyword search for “ [symbol] ,” the overall result output circuit 108 remains set.

If this overall result output is sent to the HOST, the HOST will be able to know that all three character strings “ [symbol] ,” “ [symbol] ,” and “ [symbol] ” exist between the first address and the Nth address of the character storage elements 102.

Next, if there is no tournament win via keyword searches for “ [symbol] ” and/or “ [symbol] ,” the overall result output circuit 108 is cleared.

If this overall result output is sent to the HOST, the HOST will be able to know that not all of the three character strings “ [symbol] ,” “ [symbol] ,” and “ [symbol] ” exist between the first address and the Nth address of the character storage elements 102.

As described above, the method for performing a refinement search using a plurality of search keywords 125, performing a logical sum (OR) operation on the detection results of the function that outputs the detection results of the detected character sequences 122 (character strings) in N-parallel for each byte, and outputting the presence or absence of the full-text detection results as an overall result output to the HOST substantially reduces the result output processing on the HOST side.

The present embodiment has shown a configuration where a logical sum 111 of the entire result outputs from 1 to N is taken and output externally, but it is also possible to divide the range from 1 to N into appropriate sizes and to configure a logical sum circuit 111 and an overall result output circuit 108 for outputting their result externally for each divided range.

With the above configuration, when there are many character text data 132 items of character strings shorter than the divided ranges, by storing the character strings in the respective divided ranges and performing a full-text search operation therein, the full-text search results may be obtained for the character strings stored in each range. Also, if the data size is limited, it becomes easier to find where the character string is on the HOST side.

In addition, the FG tournament circuits 113 may be configured to be capable of performing various Boolean operations, such as the direct input, logical product (AND) operation, logical sum (OR) operation, mask (ignore) operation, gap operation, as well as negation (NOT) operation, exclusive (Exclusive) operation, counter operation, and the like, as needed, in 1-bit operations with the FG shift circuits 112 to thereby enable more advanced full-text searches.

To give an example of a negation (NOT) operation, if the search keyword 125 is the character string “ [symbol] ”, when addressing a problem of a character string “ [symbol] [symbol] ” being detected as noise, this negation function is useful for finding character strings that do not contain “ [symbol] ” before “ [symbol] ” (the logical negation of “ [symbol] ”).

Similarly, the overall result output circuit 108 may be configured to be able to perform the logical product (AND) operation, logical sum (OR) operation, negation (NOT) operation, tournament sub-register, counter operation, and other required operations, full-text searches with greater convenience may be enabled by, for example, outputting the results of a plurality of batch operations (operations on long sentences) by the batch processing described below all at once at the end.

### Features of Full-Text Search of the Present Embodiment

The features of the full-text search of this full-text search processor 101 will be described.

First, the present scheme performs full-text search processing equivalent to N-gram inverted indexing in hardware, and an inverted index with any character length may be possible.

N-gram inverted indexes have a wide variety of full-text search functions and are characterized by their low rate of missed searches.

However, N-gram inverted indexes tend to grow a large number of indexes and a large index memory capacity, but the present scheme does not require the creation of indexes, so there is no need to consider the index memory capacity.

Secondly, using this full-text search processor 101 will eliminate the need for complex algorithms such as those for inverted indexes to thereby reduce the level of expertise required and experts will be no longer needed.

Also, by eliminating the language barriers between countries, it enables standardization of full-text search.

Thirdly, the full-text search algorithm of this full-text search processor 101 enables ultrafast full-text search.

Moreover, not only forward matching, middle matching, and backward matching, but also advanced processing such as the wildcard function and gap function may be processed with a minimum number of operations.

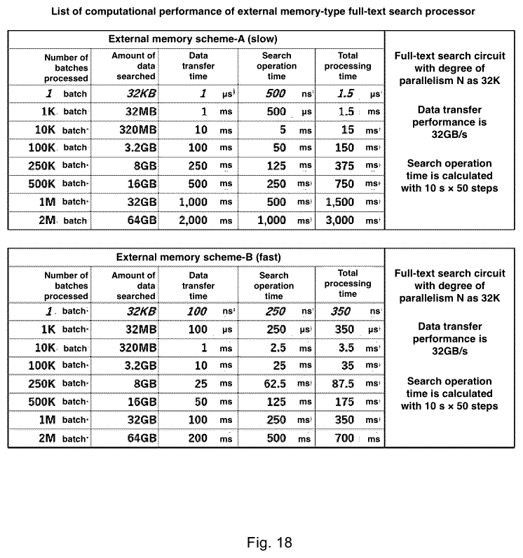

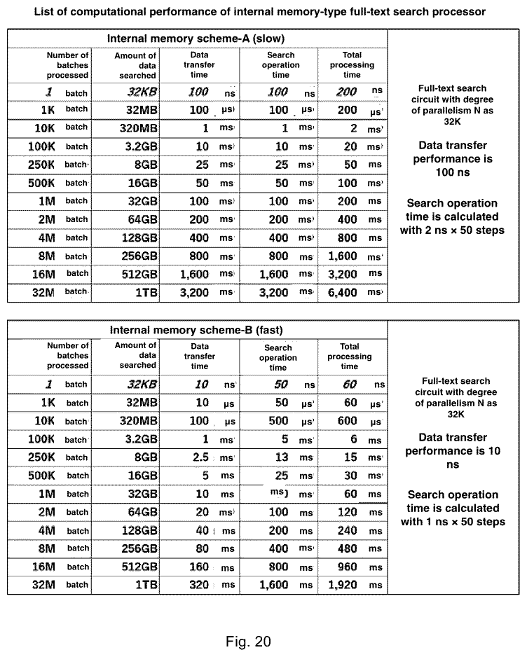

Practical examples of the processing time for full-text searches using the full-text search processor 101 will be shown in FIGS. 18 and 20 below.

The following shows an example of a configuration taking advantage of the various features of the full-text search processor 101.

### Example of External Memory-Type Full-Text Search Processor

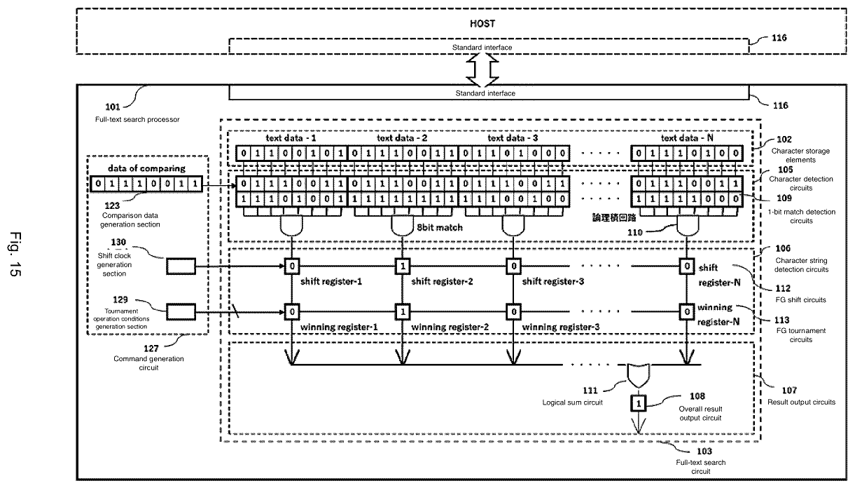

FIG. 15 shows an overview of an external memory-type full-text search processor.

As shown above, this full-text search processor 101 performs operations with N full-text search circuits 103 at a degree of parallelism N (fully parallel) to achieve efficient and high-speed character string searches, but the number of the full-text search circuits 103, N, cannot be increased infinitely.

Therefore, it is not possible to store large-sized character text data 132 in this full-text search processor 101.

A batch processing scheme solves this problem.

A HOST computer is shown above the present full-text search processor 101.

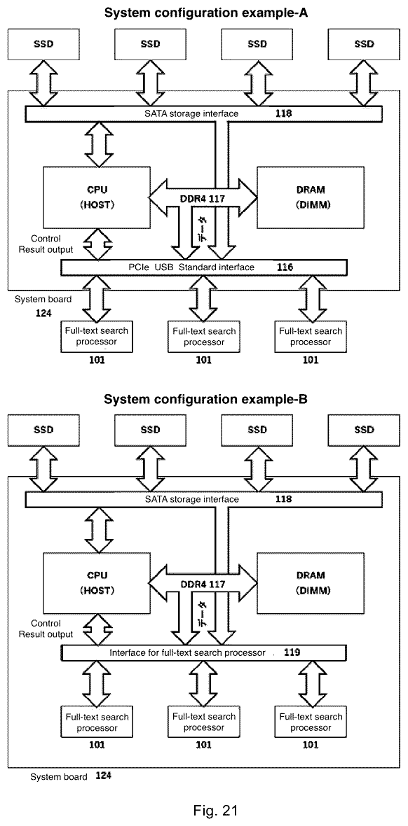

The details will be shown in FIG. 21, but this HOST computer has memories or storage.

The character text data 132 stored in these memories or storage are configured to be capable of being transferred to the full-text search processor 101 via a standard interface 116 such as PCIe or USB.

Also, the search keyword 125 from the HOST as well as the results output to the HOST are configured to be communicated via the standard interface 116.

The following describes batch processing where the number N of the full-text search circuit 103 is 32K (32×1,024) and the amount of data per batch is 32K bytes.

Note that 32K comes from an invention of Patent Document 3 “U.S. Pat. No. 5,981,666”, and is based on the degree of parallelism of parallel processing using FPGA that has been studied.

First, a case where this memory is a DRAM memory will be described.

DRAM memories are the main memory devices used in current computers, and are used in all types of computers, from servers and PCs to smartphones. These DRAM memories are rarely used alone, and are used as memory modules (DIMMs) that conform to standards such as by JEDEC (Solid State Technology Association).

The current mainstream DIMMs (Dual Inline Memory Modules) are DRAMs that conform to the DDR4 standard, with a memory capacity of about 8 GB and a data transfer capacity of between 10 GB/sec and 40 GB/sec.

When 8G bytes are used with the UTF-8 kanji 3-byte code, 8 billion bytes/3 bytes, that is, 2.6 billion Japanese characters may be stored.

### Example of Data Transfer Method

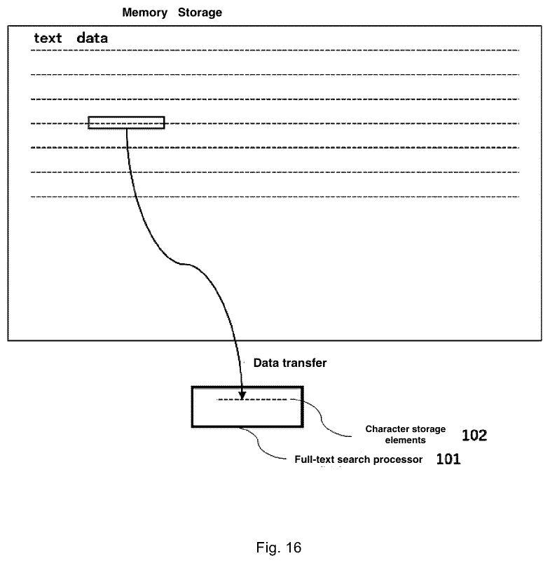

FIG. 16 illustrates an overview of data transfer between an external memory-type full-text search processor 101 and an external memory or storage.

This example shows a concept of writing text data in a DIMM memory or storage to the character storage elements 102 of the full-text search processor 101.

In this case, the HOST manages where the character text data 132 of which documents is stored or will be stored, based on the FAT (File Allocation Table), in similar way to that in normal information processing.

Similarly, reading from a memory also refers to the FAT, wherein the text data of the target text is read from the DIMM memory and a predetermined capacity of character text data 132 will be written to the full-text search processor 101.

The character text data 132 written to the DIMM memory is normally burst-transferred (written) in 64-bit (8-byte) units to the character storage elements 102 of the full-text search processor 101.

Next, a concept of transferring data from an external memory to the full-text search processor 101. will be discussed.

There are three cases for transferring text data from a memory.

If the character text data 132 to be transferred is greater than 32K bytes, the character text data 132 may be divided and sent to the full-text search processor 101 for batch processing.

When transferring batch data each time, by transferring the last several dozen bytes (maximum number of search strings) of the previous transfer in duplicate during the next transfer, omissions in the search may be eliminated.

If the character text data 132 to be transferred is smaller than 32K bytes, but close to 32K bytes, one batch may be set to one file of character text data 132.

If the character text data 132 to be transferred is significantly smaller than 32K bytes, a plurality of files of character text data 132 may be written into one batch.

Since the HOST knows what character text data 132 files were batch-processed, the operation results of this full-text search processor 101 and the character text data 132 may be associated.

### Example of Batch Processing Method

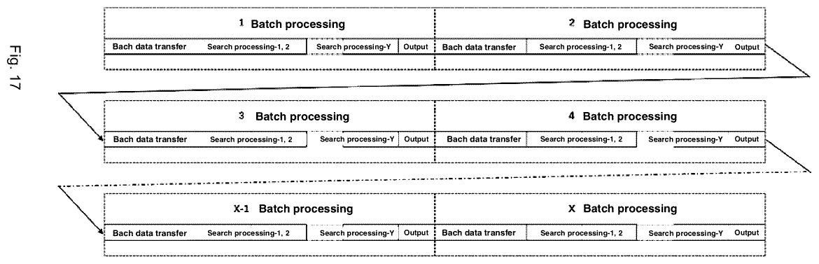

FIG. 17 describes a time chart of batch processing of the external memory-type full-text search processor.

It shows a time chart for batch processing of an external memory and the full-text search processor 101, and shows the time chart for performing batch processing from batch 1 to batch X, and Y consecutive searches from 1 to Y; and outputting a Yth search result to the HOST.

The following description shows an overview of the full-text search process when using a general-purpose DIMM memory described above and setting a batch count X to 250,000 batches.

When processing 8 GB in 250,000 batches, each batch is 32 KB.

First, a data transfer capacity is considered.

When transferring all 8 GB of data at 32 GB/sec, it takes 250 msec.

Even when the data is divided and transferred by batch processing, the total data transfer time is 250 msec.

With the assumption that a real-time search time is defined as 1 second or less, the remaining 750 msec may be used for search operations.

Conversely, the relationship between the data transfer time for each batch and the search operation time will be described as follows.

If the degree of parallelism N of the full-text search circuits 103 shown above is 32K and the amount of data per batch is 32K bytes, the number of batches X for 8 GB becomes 250,000, and when performing the full-text search within one second, the processing time of one batch will be up to 4 μsec.

With the data transfer capacity of 32 GB/sec, the data transfer time for one batch of 32 KB is 1 μsec.

Therefore, the remaining 3 μsec may be used for the search time of this full-text search processor 101.

As stated above, this full-text search processor 101 is capable of executing one time of detection processing in a few dozen steps (clocks).

As will be described in detail in FIG. 18, since the keywords for commonly seen full-text searches are two or three types of three to four characters long, 50 steps are sufficient, and if the system clock 131 is set to 10 nsec and processing of 50 steps per batch is batch-processed 250,000 (250K) times (8 GB), the operation processing time will be 125 msec.

With 250 msec (data transfer time)+125 msec (operation processing time), a total of 375 msec is a processing performance that is comparable to full-text search using indexes.

Another important feature is that the DIMM memories that are the current mainstream may be taken advantage of “as is.”

By leveraging the high-precision search capabilities and search speed performance of the N-gram scheme, fuzzy searches and synonym searches will be possible.

Since only processing at the HOST is to receive the result for each batch as to whether there are search results or not, the burden of the search is small, and the power consumption of the entire system may be reduced.

Of course, as shown in FIG. 13, it is also possible to send the search results, including the byte position of the search, to the HOST for each search processing.

### Application Example 1 of External Memory Scheme (Expansion)

The above explanation was for a single 8 GB DDR4 DIMM memory.

When increasing the capacity, expansion is easily achieved by using the same number of full-text search processors 101 as a required number of DIMMs (required capacity), and controlling them in parallel from the HOST.

In this case, the full-text search processors 101 perform search processing independently, so the full-text search time remains the same even if the memory capacity increases.

### Application Example 2 of External Memory Scheme (Non-Volatile Memory)

Since DRAMs are volatile memories, when the power is turned off, their stored data is erased and needs to be stored again.

The case where a non-volatile memory (storage) is used will be discussed below.

Data transfer capabilities of SSDs (Solid State Drives) have been improved in recent years, and there are even some that have high-speed data transfer capabilities such as 7 GB/sec.

However, when compared to the DRAM scheme with a data transfer capacity of 32 GB/s as described above, SSDs have data transfer capacities of only a fraction of that.

In such cases, by connecting a plurality of SSDs in a RAID (Redundant Arrays of Inexpensive Disks)-0 configuration, a non-volatile system with a data transfer capacity similar to that of DRAM may be achieved.

The storage capacity of SSDs is 1 TB per module or the like, which is over 100 times greater than the 8 GB DRAM-based memory described above.

Therefore, if the entire 1 TB memory space is used for character text data 132, the number of batch processes will increase by more than 100 times, and the search time will be significantly delayed.

In the 1 TB memory space, not only the character text data 132, but also various data, such as audio, video, log files, location information, sensor information, and the like may be utilized.

Since DRAMs have non-volatile data, the character text data 132 must be stored in storage somewhere.

A major feature of this scheme is that the character text data 132 stored in the SSD may be used “as is” for full-text search in real time even immediately after the power is turned on.

The full-text search processor 101 in the batch scheme with external memories or storage as described above may be implemented not only in ASICs but also in FPGAS.

Since FPGAs may add or delete functions flexibly, a full-text search processor 101 that is optimal for the system may be realized.

### (Computational Performance of External Memory-Type Full-Text Search Processor)

FIG. 18 summarizes the computational performance of the external memory-type full-text search processor described above.

The performance of the present invention is determined by the batch data transfer capacity, the degree of parallelism N of the full-text search circuits 103, the speed of the system clock 131 of computational functionality, and the batch count X.

As an example, the case of two sets of full-text searches using four Japanese characters “ [symbol] ” and “ [symbol] ,” respectively, are assumed.

In the case of Japanese UTF-8 character codes, since each character is approximately 3 bytes, each set consists of 12 bytes.

Therefore, the detection of a character string of 4 characters in one set takes 12×2−1=23 steps, and for two sets of 4 characters, it takes about 50 steps, including processing such as the result output and register clearing.

For a keyword search of English text consisting of 24 characters and 24 bytes, such as “full text search process,” it takes 24 steps for the character detection and 23 steps for the character sequence (character string) detection, with the total of about 50 steps, including processing such as the result output and register clearing.

Since the above are the search conditions for a typical search, 50 steps (clock cycles) are used as the standard number of steps (clock cycles) for a typical full-text search to summarize representative performance of the full-text search processor 101 discussed above.

An external memory scheme-A (slow) shown in the upper table of the figure is based on the full-text search processor 101 described in FIG. 15, and in this example, as described previously, the number of processing per batch is 32 KB (the degree of parallelism is 32K), the data transfer rate with the external memory is 32 GB/sec (slow), and the operation time is 50 steps at the system clock 131 of 10 nsec (slow) to thereby show the operation time per batch.

This table shows, based on the above conditions, the number of batches processed, the amount of data searched, the transfer time for transferring this data, the search operation time, and the total processing time (=data transfer time+search operation time).

Although the processing time for this scheme is slower than an internal memory scheme described below, it is characterized in that it may be used immediately with commercially available DRAMs, SSDs, and FPGAs.

The part of the table that reads “the total processing time is 375 msec with the number of processed batches 250K” is the operation performance previously shown with reference to FIG. 17.

An external memory scheme-B (fast) shown in the lower table of the figure is a summary of the operation time for each batch when an ASIC is developed and HBM (High Band Memory) with high data transfer capacity is used.

In this example, as described above, the number of processing per batch is 32 KB (the degree of parallelism is 32K), the data transfer rate with the external memory is 320 GB/s (fast), and the operation time is 50 steps at the system clock 131 of 5 nsec (fast) to thereby show the operation time per batch.

This is 4.3 times faster than the external memory scheme-A (slow).

### Example of Internal Memory-Type Full-Text Search Processor

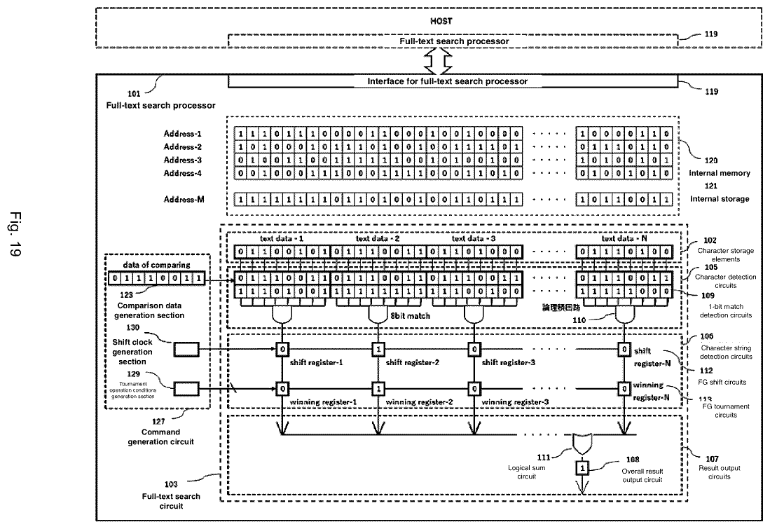

FIG. 19 shows an overview of an internal memory-type full-text search processor.

In the case of the external memory scheme described above, the memory or storage and the full-text search processor 101 were separated, and data transfer time was slow due to the bus bottleneck.

This figure shows the full-text search processor 101 implemented as an ASIC, with the data width being the same as the number of character storage elements 102, and an internal memory 120 or an internal storage 121 with addresses from 1 to M built into the full-text search processor 101.

In the figure, the internal memory 120 or the internal storage 121 with the data width from 1 to M, equal to the number of data items in the character storage elements 102 is incorporated inside the full-text search processor 101, and is configured so that, by selecting an arbitrary address, the data in the row direction may be assigned to the character storage elements 102 in full parallel.

With the above configuration, instead of transferring the character text data 132 from an external source, data transfer will be carried out by selecting arbitrary addresses from 1 to M and performing the assignment processing to (accessing) the character storage elements 102, to thereby enable full-text search processing that is faster than the batch processing described previously.

The internal memory 120 includes not only the DRAM and SRAM described above, and the internal storage 121 includes not only the NAND-type and/or NOR-type SSD memories, but also the spintronic memory and/or resistance-change memory.

Needless to say, the faster the access time, the more advantageous.

In the case of non-volatile FLUSH memories, compared to the NAND-type SSDs, NOR-type SSDs may be expected to have faster access times.

In semiconductor manufacturing technology, full-text search processors 101 that make full use of the latest semiconductor technology may be expected, such as SoC (System-on-a-Chip), SiP (System in Package), and even WoW (Wafer on Wafer) and/or 3D packaging.

An internal memory 120 and/or internal storage 121 capable of these full-text search may be also incorporated inside the FPGA.

The contents of batch processing and full-text search operations are similar to those of the external memory-type full-text search processor 101 described above. The performance of this scheme will be described below.

### (Computational Performance of Internal Memory-Type Full-Text Search Processor)

FIG. 20 summarizes the computational performance of the internal memory-type full-text search processor described above.

The internal memory scheme-A (slow) shown in the upper table of the figure is based on the full-text search processor 101 described in FIG. 19, and as described previously, the number of processing per batch is 32 KB (the degree of parallelism is 32K), assuming storage-type memory, the data transfer time for the internal memory 120 is 100 nsec (slow), and the operation time is 50 steps at a system clock 131 of 2 nsec (slow) to thereby show the operation time per batch.

This table shows, based on the above conditions, the number of batches processed, the amount of data searched, the transfer time for transferring this data, the search operation time, and the total processing time (=data transfer time+search operation time).

This scheme is 7.5 times faster than the external memory scheme-A (slow).

It is about 1.75 times faster than the external memory scheme-B (fast). The internal memory scheme-B (fast) shown in the lower table of the figure is, as described previously, with the number of processing per batch is 32 KB (the degree of parallelism is 32K), assuming a high-speed internal memory such as DRAM memory or the like, with a data transfer time of 10 nsec (fast), and the operation time is 50 steps at a system clock 131 of 1 nsec (fast) to thereby show the operation time per batch.

This scheme is 3.3 times faster than the internal memory scheme-A (slow).

This scheme is 25 times faster than the external memory scheme-A (slow).

It is 5.8 times faster than the external memory scheme-B (fast).

The amount of data searched for in both the internal memory scheme-A (slow) and internal memory scheme-B (fast) is the capacity of the memory integrated within the full-text search processor 101, so the technology for onboarding memory will be a future research theme.

If the search time of one second or less is expected, for the external memory scheme-A (slow), full-text searches with 500K batches on 16 GB of data will be possible.

For the external memory scheme-B (fast), full-text searches with 2M batches on 64 GB of data will be possible.

For the internal memory scheme-A (slow), full-text searches with 4M batches on 128 GB of data will be possible.

For the internal memory scheme-B (fast), full-text searches with 16M batches on 512 GB of data will be possible.

The performance shown in the tables is the performance of a single full-text search processor 101, so by using a plurality of full-text search processors 101 connected in parallel, the amount of data searched in the same time may be increased.

Also, since the various specifications shown in the table are based on estimates of current semiconductor technology levels, full-text search processors 101 with higher performance may be expected as semiconductor technology improves in the future.

When developing a full-text search processor 101 with an internal memory, it is a favorable to classify it into several types, such as high-speed, small capacity/medium-speed, medium capacity/low-speed, and large capacity, and select an optimal scheme by considering heat generation, chip size, and/or economic effectiveness.

Once chips are developed, users may select their optimal chip according to what performance and functions are required.

One of the advantages of this scheme is that the full-text search time may be predicted in advance as described above.

As mentioned above, the memory used for the full-text search processor 101 is not limited to the DRAM, or NAND-type and/or NOR-type storage discussed above, and new memories expected in the future may be also freely utilized.

As discussed previously, it may be incorporated in not only ASICs, but also in FPGAs.

The computational performance shown in FIGS. 18 and 20 above does not guarantee feasibility.

In addition, since they are theoretical values, certain amounts of overhead need to be taken into account.

### Example of System Configuration when Using Full-Text Search Processor

FIG. 21 illustrates system configuration examples when using full-text search processors.

There are various schemes of methods for using the external memory-type full-text search processor 101 shown in FIG. 15 and the internal memory-type full-text search processor 101 shown in FIG. 19, but two representative examples will be introduced below.

A system configuration example-A is an example of a system configuration for the external memory-type full-text search processor 101 shown in FIG. 15, in which the full-text search processors 101 are connected to and used outside of a system board 124.

This is an example of using data in a DRAM memory or data in storage from the system board 124 connected to a standard interface such as PCIe or USB 116.

The system board 124 has a DRAM memory onboard and storage connected externally.

In this case, the full-text search processors 101 receive and transmit character, via the standard interface 116, text data 132 transferred from the DRAM memory or the storage as well as search keywords 125 from the HOST and output signals of operation results to the HOST.

The maximum transmission bandwidth for USBs at present is up to 5 Gbps (USB 3.0).

On the other hand, PCIe's have a wide range of transmission capabilities from tens of GB/sec to hundreds of GB/sec, so PCIe standards may be used according to the system performance.

A system configuration example-B is an example of a system configuration for the internal memory-type full-text search processor 101 shown in FIG. 19, in which the full-text search processors 101 are incorporated to and used outside of a system board 124 with memory and storage built into the system board 124.

In this example, an interface 119 for the full-text search processors is used inside the system board 124 to perform full-text searches.

The previous discussion assumes that the HOST sends the search keyword 125 to the full-text search processor 101; that the command generation circuit 127 sends the command (control) signals for each of the steps shown in FIGS. 5 to 12 to the full-text search circuits 103; that the full-text search circuits 103 performs full-text search operations; and that the HOST receives the operation result output.

The HOST receives the search result for each batch sent from the full-text search processor 101, and if there is any batch having a result output of “presence” from the overall result output circuit 108, it may check on its own, which part of the batch data contains the search target character string.

When building a system, it is needless to say that an appropriate HOST and/or application software are prepared according to the required operation performance and functions, as well as the number of parallel full-text search processors 101.

The following, a system application embodiment of the full-text search processor 101 will be shown.

### (Web Search System-1)

Full-text searches on a web search site are extremely demanding.

This is because, in the case of web search sites, the data volume of the target character text data 132 is enormous, and also because an extremely large number of people use it regardless of the time.

Hypothetically, if 50 million Japanese people each searches on a Japanese search site on average 10 times a day, that would mean 500 million searches (50 million people×10 times)/86,400 seconds=approximately 5,787 searches per second.

With back-calculation, the processing time per search will be 1/5,787=173 μsec.

Therefore, it is necessary to be able to complete the search processing in at least half this time or less.

In the above case, the 60 μsec of the 1K batches (32 MB) of the internal memory scheme-B shown earlier is equivalent to this. This type of processor may be used, but it is also possible to write the identical data to 1,000 of the full-text search processors 101 with a 1M batches (32 GB) and 60 msec for distributed processing.

When mounting on a semiconductor chip and/or mounting the semiconductor chip on a printed circuit board, it is more advantageous to use a large chip than to use many small chips.

Considering the multi-accessing as above, it is favorable to use the full-text search processors 101 with appropriate performance.

Common web search sites currently use HDD-type storage systems from the perspective of reducing system costs, but it is thought that they will gradually be replaced by SSD-type storage in the future when the cost of SSD-type storage is reduced.

In that case, if a full-text search engine using this scheme is used, various restrictions of the indexing will be lifted and it may be expected that the system operating costs will be reduced to thereby create a highly real-time web search system.

### (Web Search System-2)

In order to replace the web search sites described above with this scheme, it is thought that considerable time will be required including consideration of economic factors such as the introduction cost and operating cost.

We will introduce a method that may be implemented relatively easily and that takes advantage of the features of this technology.

According to information from a major web search site, a type frequency in a Japanese N-gram scheme (maximum number of indexes) is published on the Internet as follows.
https://japan.googleblog.com/2007/11/n-gram.html
Total number of words: 255,198,240,937 (255 billion)
Total number of sentences: 20,036,793,177 (20 billion)
1-gram type frequency: 2,565,424
2-gram type frequency: 80,513,289
3-gram type frequency: 394,482,216
4-gram type frequency: 707,787,333
5-gram type frequency: 776,378,943
6-gram type frequency: 688,782,933
7-gram type frequency: 570,204,252
The type frequency corresponds to the maximum number of indexes.

The 1-gram type frequency refers to single characters, and includes not only commonly used kanji and English letters, but also characters and symbols used worldwide, as well as environment-dependent characters and the like, resulting in 2.56 million types of characters appearing.

Even for indexes with low frequency of occurrence, if ignored, there will be missed searches.

Since even special characters or symbols which are respectively used only once in a total of 20 billion sentences need to have their own indexes, when creating indexes in the N-gram indexing, an enormous number of indexes will be needed totaling as much as 3.2 billion.

What needs to be considered is that even if most of the 3.2 billion indexes are rarely used as above, if they are ignored, missed searches will occur.

Therefore, we have no choice but to use a complex index structure configuration, for example, using other types of indexes, such as morphological indexes, in combination.

A method for solving this index conundrum that has persisted for many years will be introduced below.

As an example, by using the present full-text search processor 101 if the text contains even one rarely used character and/or special symbol, such as the characters “ [symbol] ,” “ [symbol] ,” “ [symbol] ,” “ [symbol] ,” “ [symbol] ,” “ [symbol] ,” or the like; and using the conventional index-based full-text search as before if the text does not contain those rarely used characters and/or special symbols, the system may be made substantially more efficient.

Since the frequency of full-text searches for rarely used characters will be extremely low, the full-text search processor 101 may be selected based on the search speed that is appropriate for that frequency of searches.

If the need for indexes that include rarely used characters is eliminated, the number of indexes will be extremely small.

Also, since the present full-text search processors 101 only needs to store text data from websites that include rarely used characters, the number of full-text search processors 101 may be reduced.

For example, in possible applications, indexes may be determined for only the top 100,000 most frequently used terms, and full-text searches will be applied to only these 100,000 indexes; whereas searches for all other less frequently used indexes will be performed by the present full-text search processor 101.

If the number of indexes, which until now has required more than 3.2 billion, may be reduced to 100,000 and the addition of indexes becomes unnecessary, the complexity of conventional web search systems will change completely.

As described above, by combining the advantages of the indexing scheme and the full-text search scheme, the number of indexes may be reduced to the minimum without compromising the search performance, and the web search systems may be slimmed down

The problem of the number of indexes described above is a common issue for full-text searches, not just for web search systems.

In the previous example, a system configuration was shown, where it uses the full-text search processor 101 when even one special symbol or rarely used character is included, but it is also possible not to perform the full-text search and/or the system configuration may be used for specific characters other than special symbols or rarely used characters.

It is favorable to analyze the system features to consider the optimal way to use it.

### (Local Web Search System)

When searching for characters contained in academic papers, documents, etc., sometimes the search methods used by ordinary web search sites may not be sufficient.

In such cases, by collecting the necessary information from the web and using the full-text search processor 101 of the present invention, full-text searches using advanced methods such as grep (global regular expression print) may be possible.

### (Detection of Errors in Characters and Terms, Detection of Mistranslations)

A corpus is a database used for natural language research.

Since a corpus is a database that uses indexes, it is revised regularly in a similar way to that of dictionary compilation, and therefore, the latest words, such as “COVID crisis” are not included often times.

By using the present invention, a corpus may be made as text data which always includes the latest terms and information.

By comparing a part of a sentence being composed with text data that incorporates a large amount of the latest information stored in internal or external memories, it may also be utilized in such a way that, if there is no matching text, it is judged to be unprecedented (an error) and an alert is output.

(Large-Scale Infrastructure System, Large-Scale in-House Search System)

Needless to say, the present invention is most suited for full-text search systems for large-scale infrastructures and/or large organizations, such as patent searches, in-house search systems for large companies, and the like.

It is favorable to build a system by referring to the contents of the web search site described above.

### (Untapped Fields of Implementation)

The present invention is expected to shed light on systems that have problems with full-text searches using indexes and/or fields that have not yet been systematized.

It is expected to be applied to full-text searches of stream-type text data that discovers value in new information.

The frequency of characters used in text data that flows in as stream data is essential for AI analysis.

It is favorable to focus on real-time processing of natural language processing, statistical systems, and the like, which are difficult to accommodate with the current schemes.

For example, by matching recognition candidates of speech recognition and/or translation candidates of translation with the full-text search processor 101, if there are no matching texts, it may be determined as unprecedented (an error) and an alert may be output, candidates with the most matching text may be selected, or the like, and it may be used for intelligent information processing (AI field) to improve the accuracy of speech recognition, for example.

### (Personal Use)

Many people who use PCs frequently search for emails, and use various full-text searches for text data such as in Word, Excel, and PowerPoint on a daily basis.

However, these full-text searches are performed by standard software that comes with PCs, and advanced search conditions may not be set.

The full-text search according to the present invention eliminates the need for any expertise at all, and it is expected that the standardization of software with various functions will progress.

By using these pieces of software, even non-experts of full-text search or software may use full-text search as they wish, respectively.

### (Genome Analysis)

The above discussion has been about searching character text data 132, but the present full-text search processor 101 may also be used for genome analysis.

The human genome contains approximately 6 billion base pairs of DNA in the nucleus.

Therefore, if there is a capacity of 8 GB, the entire human genome may be stored and analyzed all at once.

Since the wildcard function and gap function are essential in the genome analysis of “ATGC” base sequences, the present scheme is optimal.

Most current genome analyses use indexes to speed up the process, and depending on how the indexes are created, problems arise due to missed searches or inconsistent search results.

Also, the time taken to create indexes is a waiting time.

By using the present full-text search processor 101, there is no indexing, that is, no waiting time, there is no missed searches or inconsistent search results, and even high-speed genome analyses will be enabled.

### (Standardization of Full-Text Search)

The full-text search according to the present invention may be used universally for all characters worldwide by using a world standard character code such as UTF-8.

By introducing the rules of character pattern matching such as regular expressions of SQL and NonSQL grep and the like, full-text search technology across the globe may be standardized

Standardization will make it possible to supply the ASIC chip for the present full-text search processor 101 at a low cost, and a large demand is expected.

### (Merits of the Present Invention)

The merits of the full-text search processor 101 of the present invention and systems and products that use it will be listed below.

### No Need for Inverted Indexes

Enables real-time processing and stream processing
Eliminates need for index tuning
Eliminates need for index memory and/or storage
Eliminates need for index update processing
Facilitates system development
Facilitates system expansion

### Accuracy and Speed Functions

Has similar search accuracy and search speed to those of N-gram
Wildcard, gap, and intermediate matching and backward matching are possible

### (Character Searches Similar to SQL's Like Statement or Grep (Regular Expression) are Possible)

### Versatility

Enabled to support character encodings such as ASCII, JIS, and UTF
May be used for genome analysis, etc.
Enabled to standardize full-text searches worldwide with the UTF-8 character code
May be used for SQL and non-SQL databases

### Practicality

May be used it in FPGAs
May be incorporated into full-text search systems that use indexes
May create corpora with the latest terminology

### Contributions to Information Processing

Reduces the expertise required for full-text search technology, making specialists unnecessary
Accelerates the evolution of natural language processing technology, such as speech recognition and translation
May standardize full-text search technology worldwide

Many of the above are overt or potential needs in full-text searches and natural language processing technology.

### (Focus of the Present Invention)

Lastly, the focus of the present invention will be shown.

It would be ideal to use the full-text search circuit 103 for every single byte of character text data 132, but this scheme would result in extremely poor cost performance for full-text search semiconductor chips and full-text search systems.

The present invention is intended to balance the performance of full-text search without the need for indexing and the system cost by providing many character text data 132 items to the full-text search circuit 103 in a time-sharing manner.

Note that, this example is described such that it provides all of the circuits (functions) of the command generation circuit 127 inside the full-text search processor 101, but some of the circuits (functions) or all of the circuits (functions) of the command generation circuit 127 may be provided on the HOST side, and the full-text search processor 101 executes operations based on the operation conditions for each step given by the HOST side, and notifies the HOST side of the acknowledge (ACK) for each step each time.

In addition, when the command generation circuit 127 is placed inside the full-text search processor 101, the CPU and the memory for storing the program may be incorporated inside the full-text search processor 101, and software processing is used to generate the full-text search operation conditions 114 and control the full-text search circuit 103.

### Basic Circuit Configuration (Second Example)

Next, a second example of the full-text search processor according to the present invention will be described.

In this second example, as in the first example above, the character text data to be searched is stored in a storage element for each byte (8 bits), “characters” and “character sequences” of a given search keyword 125 are compared in parallel byte by byte for their match or mismatch, and the position (address) of the character text data corresponding to the beginning or end of the given search keyword 125 character string is returned as the full-text search result.

However, in the previous first example, the shift operation by the character string detection circuits 106 was performed after the character detection by the character detection circuits 105 was completed, whereas in this second example, the character detection by the character detection circuits 105 and the shift operation by the character string detection circuits 106 are performed “alternately.”

In other words, in the first example, the character detection circuits 105 were first made to detect as the match flags (FGs) respective characters or parts of a character (1-byte code) that match all the characters contained in the search keyword 125 in the character text data 132, and then, the character string detection circuits 106 were made to shift the position of these flags by n−1 times (corresponding to the number of shift clocks mentioned above) to thereby detect the position of consecutive flags whose number corresponds to the number of bytes of the search keyword 125, i.e., the character sequence 122 (character string).

In contrast, in this second example, whenever a character or part of a character (1-byte code) that matches the search keyword 125 is detected (with the match flag (FG)), the position of this flag is shifted by one, and the FG tournament circuits 113 detects whether the flag is consecutive with the position of the flag detected immediately before it for each character code. Even with such a method, the character sequence 122 (character string) may be detected. Hereafter, such a processing with this second method is referred to as “alternate processing.”

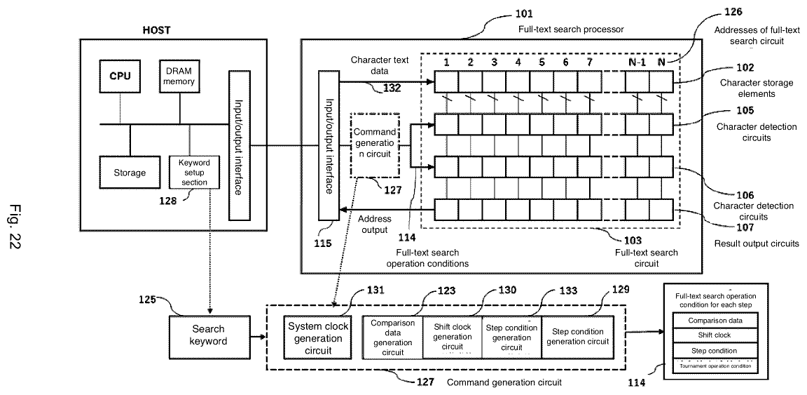

FIG. 22 shows the basic configuration of the full-text search processor for executing this second example. In this second example, a step condition generation circuit 133 is added, to the second example command generation circuit 127 (FIG. 1), for generating a step condition 133 (in this example, a signal that is a logical “0” for Step 1 and a logical “1” for steps other than Step 1 (described below)) to implement the above alternate processing.

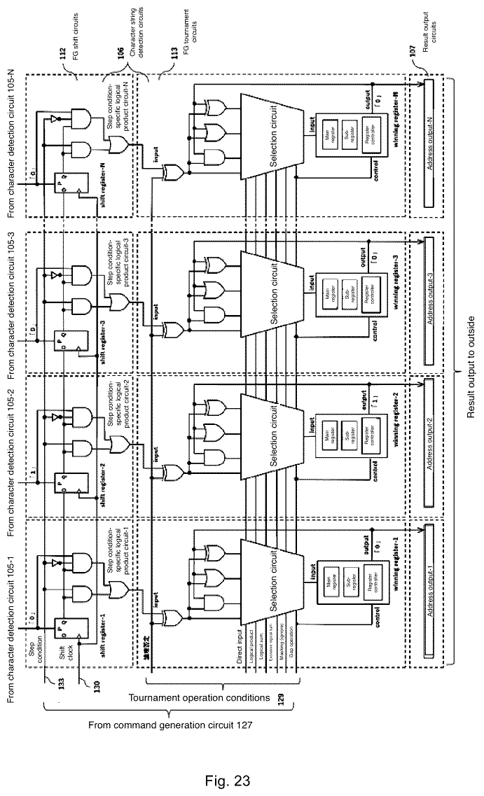

Also, FIG. 23 corresponds to FIG. 3 of the first example, and step condition-specific logical product circuits 134, connected to the FG shift circuits 112, are provided in the character string detection circuits 106 of FIG. 3.

These step condition generation circuit 133 and the step condition-specific logical product circuits 134 enable the alternate processing.

Note that the step condition-specific logical product circuits 134 are not limited to this configuration, but as shown in FIG. 23, they are each composed of a two-input logical product (AND) circuit, a three-input logical product (AND) circuit, and a logical negation (NOT) circuit.

The following describes the alternate processing in detail with reference to these circuits.

### Alternate Processing Operations in Second Example: Command Generation Operation

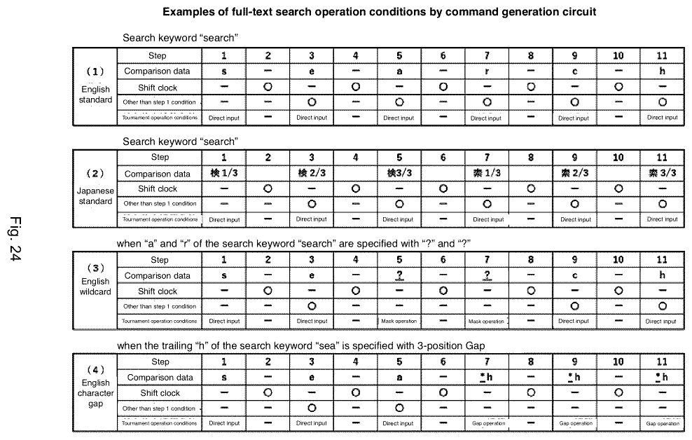

FIG. 24 corresponds to FIG. 4, and shows specific examples (1) to (4) of the full-text search operation condition commands generated by the command generation circuit 127 in this second example.

In this second example, unlike the first example (FIG. 4), the command generation circuit 127 structures commands of Steps 1-11 so that search operations for the characters and character string are carried out alternately. In order to enable this alternate processing, this second example differs from the first in that 1) the fourth command 127 given by the step condition generation circuit 133 is added as a step condition 133 (in this example, the signal that is a logical “0” for Step 1 and a logical “1” for steps other than Step 1), 2) the flag shift direction is rightward instead of leftward, and 3) all of the tournament conditions given are “direct input.”

### Full-Text Search Operations in the Second Example

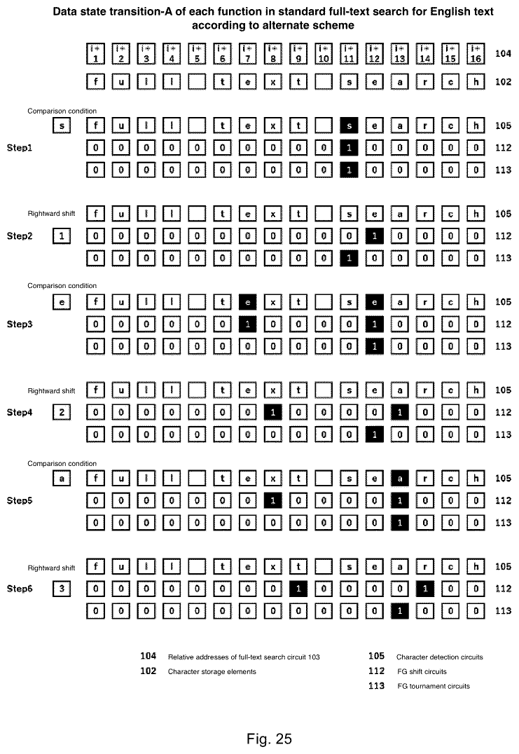

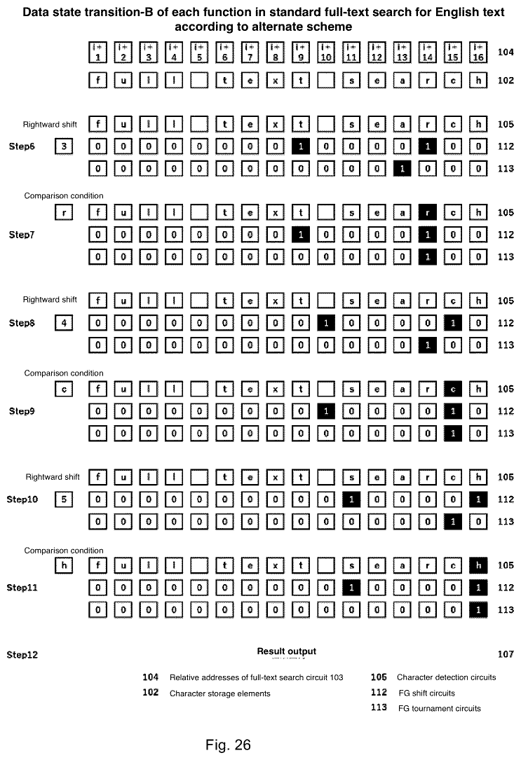

Next, the data state transitions for the full-text search in this second example will be described with reference to FIG. 25 and FIG. 26.

Note that the search target is the same as in the first example (FIG. 5 and FIG. 6), and the search character “search” is searched for in the character text data 132 of “full text search.” The number of processing steps is also the same as in the first example above, i.e., 11 steps.

The processing for each step (1-11) is performed by the full-text search circuits 103 using the commands (comparison data 123, shift clock 130, step condition 133, and tournament operation conditions 129) provided by the command generation circuit 127.

First, in Step 1, the character “s,” composed of a single byte, is detected, and as in step 1 of the first example above, the character detection circuit 105 at a relative 11th address detects “s.” This detection result is preset as a flag (FG) in the FG shift circuit 112. In this example in FIG. 25, since the only occurrence of the letter “s” in the “full text search” is at the 11th address, only the FG shift circuit 112 at this relative 11th address is set to the logical “1”, and the logic of the FG shift circuits at other addresses will be “0.”

Further, this FG value (operation result) is processed by the step condition-specific logical product circuits 134 and entered to the FG tournament circuit 113. In the case of Step 1, the fourth command 127 given by the step condition generation circuit 133, i.e., the step condition 133 (in this example, the signal that is a logical “0” for Step 1 and a logical “1” for steps other than Step 1) is “0”, so the two-input logical product (AND) circuit of the step condition-specific logical product circuit 134 becomes valid, and this operation result is entered to the FG tournament circuit 113 via the logical sum (OR) circuit.

As shown in FIG. 24 (1), since the operation condition for the FG tournament circuits 113 in Step 1 is specified as “direct input”, the FG tournament circuit 113 (register) at the relative 11th address is set to logical “1”, and the other addresses are set to logical “0” (see Step 1 in FIG. 25).

In other words, in Step 1 (the first step), the operation result of the character detection circuits 105 is configured to be set directly to the FG tournament circuits 113.

In Step 2, all FGs set in the FG shift circuits 112 are relatively shifted by one address to the right by the shift clock 130 signal, and the FGs are set in the FG shift circuits to the right (Step 2 in FIG. 25). At this time, the logical states of the FG tournament circuits 113 do not change.

Thus, in Step 1, character detection is performed, and in Step 2, the shift of the flags for character string detection is performed. Hereafter, the character detection and the shifting are performed alternately as above.

Next, in Step 3, the detection of the second character, “e”, is performed. In this example, as shown in FIG. 25, the “e” characters at the relative 7th and 12th addresses are detected.

The detection results at the 7th address and the 12th address are input to the FG shift circuits 112. At this time, the FG shift circuit 112 at the 12th address already has the flag (logical “1”) shifted from the 11th address in the above Step 2, and the following operation will be performed.

In other words, at the 12th address, the logical value entered from the character detection circuit 105 and the logical value preset in the FG shift circuit 112 are both “1”, and the fourth command 127 (the signal that is a logical “0” for Step 1 and a logical “1” for steps other than Step 1) given by the step condition generation circuit 133 is “1”, so the three-input logical product (AND) circuit of the step condition-specific logical product circuits 134 becomes valid, and that operation result (logical “1”) is entered to the FG tournament circuit 113 via the logical sum (OR) circuit. Then, as shown in (1) of FIG. 24, the FG tournament circuits 113 are given a “direct input” command, so in this example, the relative 12th address in the FG tournament circuits 113 is set with the logical value “1” (see the value of the 12th address in Step 3 of FIG. 25)

On the other hand, as for the 7th address, since the logical value preset in the FG shift circuit 112 is “0”, as a result of the same operation as above, the logical value set in the FG tournament circuit 113 will be “0,” and it is processed as noise.

As for the addresses other than the above 11th and 7 the addresses, since the logical value input from the character detection circuits 105 and the logical value preset in the FG shift circuits 112 are both “0”, as a result of the same operation as above, the logical value set in the FG tournament circuits 113 will be “0.”

In other words, the FG tournament circuit 113 at the relative 11th address, which had a logical “1” set up to Step 2, is cleared to “0” because the logical product (AND) condition of both the character detection circuit 105 and the FG shift circuit 112 does not hold.

That is, the major difference from the conventional method is that, in the steps after Step 1 (the first step), in Step 3 in this example, the tournament survivor FG is updated in the FG tournament circuit 113 at the address where the logical product (AND) condition between the operation result of the character detection circuit 105 and the FG shift circuit 112 is satisfied.

As for Step 4 to Step 9, since similar operations to those as above are repeated, their descriptions are omitted.

Step 10 shows a state where the FG of the FG shift circuit 112 shown in Step 9 has been further shifted by one byte to the right (a total of 5 shifts to the right). In this Step 10, as shown in FIG. 26, the logical values of the 11th and 16th addresses of the FG shift circuits 112 are set to “1”, and the relative 15th address of the FG tournament circuits 113 is the tournament survivor address at this point.

In Step 11, the logical product (AND) condition is satisfied because both the FGs of the character detection circuit 105 and the FG shift circuit 112 at the relative 16th address exist, so the relative 16th address of the FG tournament circuits 113 becomes “1” and the relative 15th address is rewritten as “0.”

Therefore, the relative 16th address becomes the final tournament winner address.

The above processing detected that the character sequence 122 (character string) from the relative 11th address to the relative 16th address is the same as the character sequence 122 (character string) of the given search keyword 125 conditions, and that the address that matches the character code at the end of the given search keyword 125 has been detected.

In this second example, unlike the first example, the validity of the sequence for each character code of detected character codes may be determined Whereas, the number of operational steps to be executed is the same as in the first example, which is n×2−1 times, i.e., 11 steps in this case, where n is the number of bytes in the given comparison data 123. In other words, compared to the first example, more accurate operations may be performed with the same number of steps. That is, this second example is a method for updating the tournament survivor FG each time a new character is detected, so it is characterized in that the validity of the sequence of the entire character string searched may be guaranteed, and it has high search accuracy and a fast search speed.

Note that, in Step 12, the above operation results are output from the result output circuits 107, but unlike the first example, the output is not the starting address, but the last address.

However, when searching for the given search keyword 125, the search keyword 125 does not necessarily need to be searched from the beginning of its character string, as in “search,” and the search may be performed from the end of the character string, as in “hcraes.” In that case, the shift operation of the shift register may be leftwards, and the first address “s” should be detected.

### Standard Full-Text Search Operations for Japanese Text in Second Example

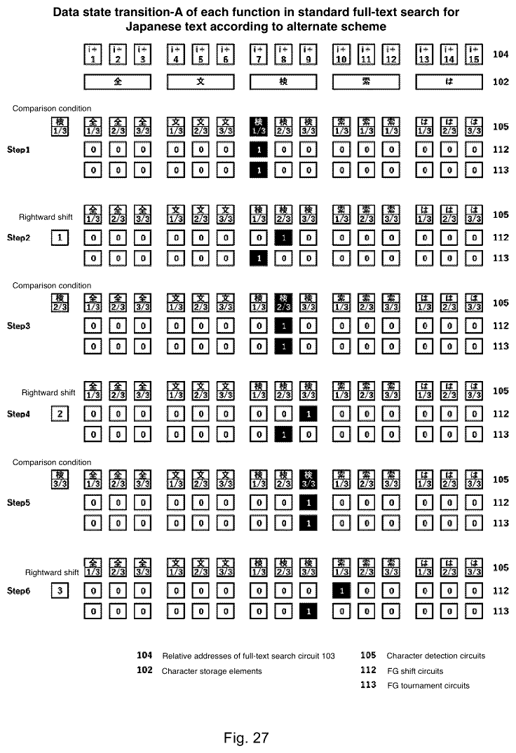

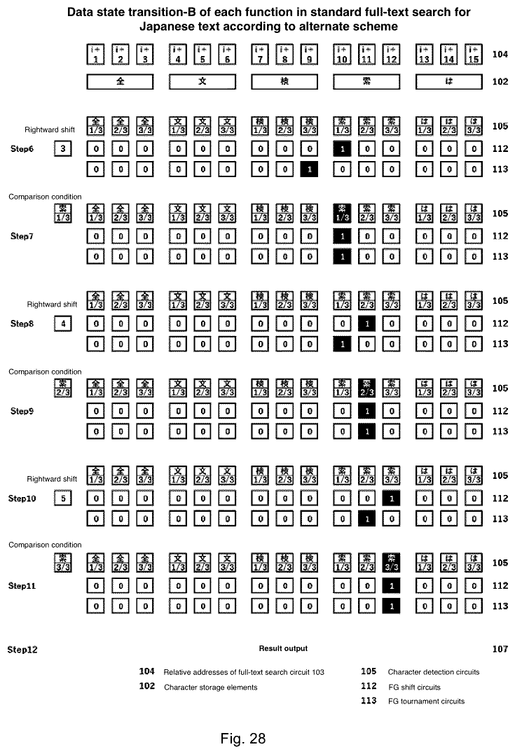

FIGS. 27 and 28 illustrate the data state transitions of each function of the standard full-text search for Japanese text in the second example, which corresponds to FIGS. 7 and 8 in the first example.

This processing sequentially provides the full-text search circuits 103 with the commands shown in (2) of FIG. 24 (comparison data 123, step condition 133, shift clock 130, and tournament operation conditions 129) sequentially in steps, and based on these commands, the full-text search circuits 103 perform full-text search processing.

While the detailed processing based on the above commands is omitted from the discussion, in the case of Japanese text, one character becomes a plurality of bytes (three bytes in this example), but the content of operations are the same as for English text.

Step 1 to Step 5 detect the character codes for “ [symbol] : 1/3,” “ [symbol] : 2/3,” and “ [symbol] : 3/3” from the character text data 132 of “ [symbol] ” stored, and Step 6 shows the shift operation as a pre-processing for detecting the character code for “ [symbol] : 1/3.”

In the final Step 11, by giving the comparison condition “ [symbol] : 3/3,” as described previously, the FGs exist at the relative 12th address of both the character detection circuits 105 and the FG shift circuits 112, and the logical product (AND) condition is satisfied, so the relative 11th address of the FG tournament circuits 113 becomes “1”, and the relative 11th address is the final tournament winner address.

The above processing detected that the character sequence 122 (character string) from the relative 7th address to the relative 12th address matches the character sequence 122 (character string) of the given search keyword 125, and the the address 126 of the full-text search circuits that matches the character code at the end of the given search keyword 125 is output as the search result.

### Full-Text Search Operations when Wildcard is Applied in Second Example

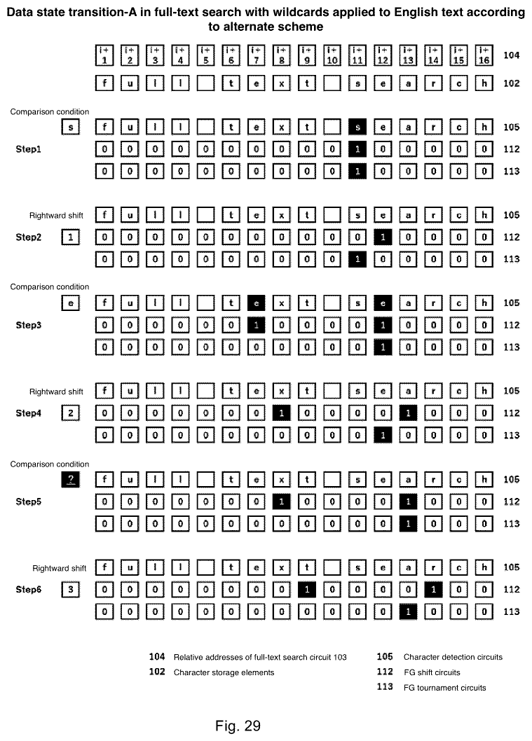

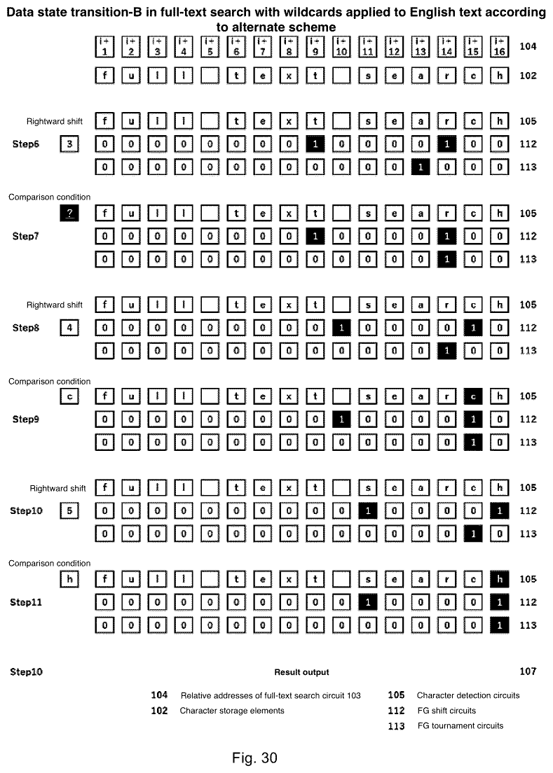

FIGS. 29 and 30 illustrate the data state transitions of the full-text search with the wildcard applied to English text in the second example, corresponding to FIGS. 9 and 10 in the first example.

This processing provides the full-text search circuits 103 with the commands shown in (3) of FIG. 24 (comparison data 123, step condition 133, shift clock 130, and tournament operation conditions 129) sequentially in steps, and based on these commands, the full-text search circuits 103 perform full-text search processing.

While the detailed processing based on the above commands is omitted from the discussion, in this example, the third and fourth characters of the character string “search” contain the wildcard “2,” but the content of operations is basically the same as the previous two examples.

In other words, Step 1 to Step 4 of the character detection are as described previously.

In the case of wildcards in Steps 5 and 7, the FG tournament circuits 113 are given the Mask (ignore) operation condition as shown in FIG. 24, and by giving a similar processing to that of when the character detection circuits 105 had a match with any character, the FG tournament circuits 113 will execute a predetermined tournament operation.

The processing hereafter is the same as in the previous description, so its explanation will be omitted, but in this example, too, the address corresponding to the character code at the end of the given search keyword 125 has been detected.

While this example shows the case where wildcards were specified in the middle of a character string, a wildcard may be used not only in the middle of a character string, but also at any position, such as the beginning or end.

This method, as above, enables wildcard processing when a wildcard is contained in the character string of the externally provided search keyword 125 by configuring the processing for wildcards so that the tournament winning condition is satisfied regardless of the characters.

(Full-Text Search when Character Gap is Applied)

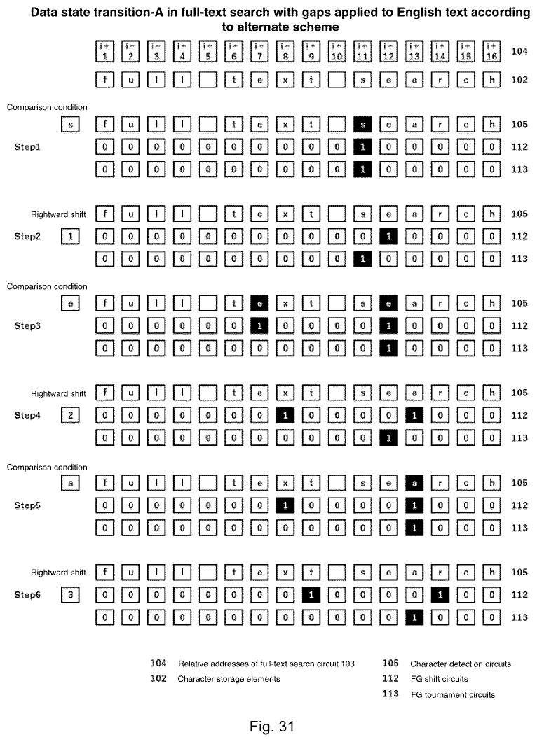

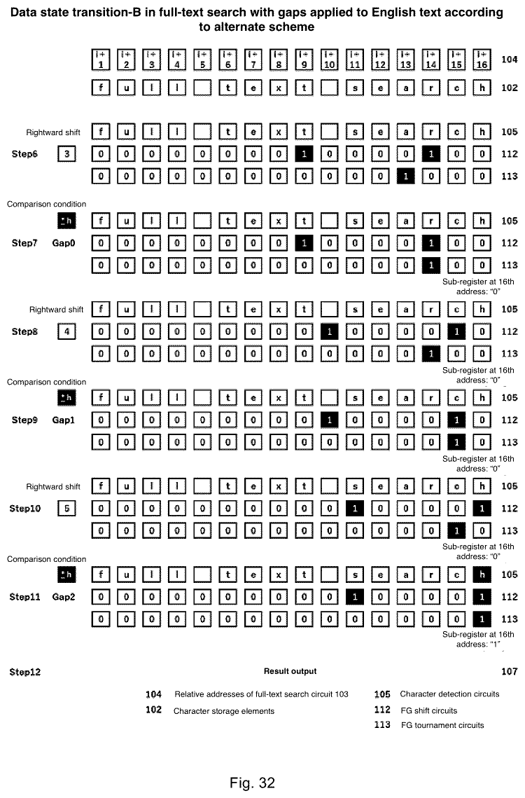

FIGS. 31 and 32 illustrate the data state transitions of the full-text search with the gap applied to English text in the second example, corresponding to FIGS. 11 and 10 in the first example.

This processing provides the full-text search circuits 103 with the commands shown in (4) of FIG. 24 (comparison data 123, step condition 133, shift clock 130, and tournament operation conditions 129) sequentially in steps, and based on these commands, the full-text search circuits 103 perform full-text search processing.

While the detailed processing based on the above commands is omitted from the discussion, this example is the case where “sea” is certain and thereafter, a character “h” is assumed to follow within three places of Gap from 0 to 2 (Gap3), that is, Gap0: “seah,” Gap1: “sea*h,” Gap2: “sea**h” are all considered to be matches, and the other operations are similar to the previous three examples.

In other words, the character detection of “sea” from Step 1 to Step 6 is as described previously.

In Steps 7, 9 and 11, Gap3 for Gap0, 1 and 2 is specified as the special character “*h.” The Gap processing determines that the character string is valid and a match if there is a character “h” in any of Steps 7, 9 and 11.

In order to perform such operations, this second example uses the sub-registers of the FG tournament circuits 113.

In other words, as shown in FIG. 24, if “h” is specified in Step 7, the FG tournament circuits 113 are given the Gap operation condition, and as in the wildcard case, in this example, regardless of what character is in the relative 14th address, the tournament winning operation is completed.

Further, the sub-registers are operated to store, in the sub-register of the relative 16th address, which is two addresses ahead of the tournament survivor relative 14th address, the fact that the relative 14th address was not “h.” Therefore, the sub-register of the relative 16th address is set to “0.”

When “h” is specified in Step 9, a similar processing applies as above. In this step also, the relative 15th address is not “h”, so the sub-register of the relative 16th address, which is one address ahead of the surviving relative 15th address, is written with “0”, and remains a logical “0.”

When “h” is specified in Step 11, the logic of the character detection circuit 105 at the relative 16th address becomes “1”, and the main register at the relative 16th address of the FG tournament circuits 113 becomes “1.”

Further at the relative 16th address, the sub-register is written with a “1” and its logic becomes “1,” and the main register is also “1.”

Since the logic of both the main and sub registers is “1,” it is determined that at least one of the three Gap-specified locations contains the character “h”, and the relative 16th address becomes the final tournament winner address.

As in the previous discussion, in this example, too, the address 126 of the full-text search circuits corresponding to the last character code of the given search keyword 125 was detected.

The above description was about the condition that was met in the final step of Gap2, but needless to say, these operations may be performed so that this tournament will have a survivor even if the sub-registers were set to “1” in Gap0, i.e., Step 7, and Gap1, i.e., Step 9.

The above operations and output enables the full-text search of character strings that include gaps between characters, such as “seah,” “sea*h,” and “sea**h.”

Although the discussion is omitted, the Gap may be set at any position by detecting the character string from the back.

With the wildcard function and Gap function as above, the convenience of full-text search operations may be improved.

It is particularly important that advanced full-text searches such as the wildcard function and Gap function may be processed in a similar number of steps to those of standard full-text searches.

The present invention is not limited by the two embodiments described above, and various changes and modifications may be made without departing from the scope and spirit of the invention.

### DESCRIPTION OF THE REFERENCE NUMBERS

101: Full-text search processor
102: Character storage element
103: Full-text search circuit
104: Relative address of full-text search circuit
105: Character detection circuit
106: Character string detection circuit
107: Result output circuit
108: Overall result output circuit
109: 1-bit match detection circuit
110: Logical product (AND) circuit
111: Logical sum (OR) circuit
112: FG (Flag) shift circuit
113: FG (Flag) tournament circuit
114: Full-text search operation condition
115: Input/output interface
116: Standard interface
117: DRAM interface
118: Storage interface
119: Interface for full-text search processor
120: Internal memory
121: Internal storage (including SSD)
122: Character sequence
123: Comparison data (generation circuit)
124: System board
125: Search keyword
126: Address of full-text search circuit
127: Command generation circuit
128: Keyword setting function
129: Tournament operation conditions (generation circuit)
130: Shift clock (generation circuit)
131: System clock (generation circuit)
132: Character text data
133: Step condition (generation circuit)
134: Step condition-specific logical product circuit

What is claimed is:

1. A full-text search processor consisting of semiconductor devices intended for full-text keyword searches, the full-text search processor comprising:
character storage elements for receiving search target text data to be searched through, and assigning and temporarily storing therein, a coded character string included in the text data to a first address to an Nth address byte by byte;
character detection circuits for detecting storage positions, on the character storage elements, of all of coded characters included in a search keyword by sequentially receiving one or more coded characters included in the search keyword byte by byte as comparison data, comparing each of the comparison data with the coded character string stored on the character storage elements in N-parallel, and repeating it for all of the coded characters included in the search keyword;
character string detection circuits for detecting positions on the character storage elements where all of the coded characters included in the search keyword exist consecutively in the same order as in the search keyword; and
result output circuits for receiving search results of the character string detection circuits and outputting a position of the beginning or a position of the end of the consecutive character string.

2. The full-text search processor of claim 1, wherein
the character detection circuits comprise
N sets of eight 1-bit match or mismatch operational circuits, connected to each address of the character storage elements, for comparing a 1-byte/8-bit code of the text data stored at each address and a 1-byte/8-bit code constituting the comparison data, and detecting a bit-by-bit match or mismatch; and
N logic operation (logical product (AND), logical sum (OR), and/or logical negation (NOT)) circuits for receiving 8 bits of result output from each set of the 1-bit match or mismatch operational circuits, and detecting a match or mismatch between a character code of the coded characters of the text data stored at each address and a character code of coded characters constituting the comparison data.

3. The full-text search processor of claim 1, wherein
the character string detection circuit is
composed of two circuits: an FG shift circuit and an FG tournament circuit for determining validity of a FG (flag) at the character storage position detected by the character detection circuit and a FG (flag) sequence at the detected character storage positions, and
the FG shift circuit and the FG tournament circuit are circuits for detecting in N-parallel, a position (address) of the beginning or a position (address) of the end of the character codes of the character string on the character storage elements, which the character string matching the character string specified by the search keyword, by referring to a sequence of the character codes of coded characters included in the search keyword and repeatedly determining the validity of a sequence of adjacent character codes in the character codes of the character string on the character storage elements, assigned and stored at the first address to the Nth address.

4. The full-text search processor of claim 1, wherein
the character string detection circuits comprise
N of FG shift circuits for storing operation results of the character detection circuits as flags as well as shifting the stored FGs in N-parallel; and
N of FG tournament circuits for performing tournament operations on the FGs by shifting the FGs, stored by the FG shift circuits, in N-parallel while performing N-parallel logic operations on the FGs with the pre-shifting FGs, and repeating the same for all of the coded characters included in the search keyword.

5. The full-text search processor of claim 1, wherein
when the search keyword is constituted with n-byte coded characters,
the number of shifts of the FG shift circuits and its associated the number of tournament operations by the FG tournament operational circuits are n×2−1 times, respectively.

6. The full-text search processor of claim 1, wherein
the FG tournament circuits comprise a function for enabling masking (ignoring) of operations and enable a full-text search when a wildcard is used in the search keyword.

7. The full-text search processor of claim 1, wherein
the FG tournament circuit is incorporated with two pairs of registers and enable a full-text search when the search keyword includes a character gap.

8. The full-text search processor of claim 1, wherein
the full-text search processor performs a logical sum (OR) operation on the N-parallel (full parallel) detection results output by the result output circuits, and outputs presence or absence of full-text search operations.

9. The full-text search processor of claim 1, wherein
the full-text search processor transfers text data, which is in memories or storage external to the full-text search processor, to character storage elements, which are for temporarily storing the N-byte character text data, as batch data; and repeats the full-text search operations in N-parallel (full parallel).

10. The full-text search processor of claim 1, wherein
the full-text search processor transfers text data, which is in memories or storage inside the full-text search processor, to character storage elements, which are for temporarily storing the N-byte character text data, as batch data; and repeats the full-text search operations in N-parallel (full parallel).

11. The full-text search processor of claim 1, wherein
the full-text search processor is implemented in ASICs and FPGAs.

12. The full-text search processor of claim 1, wherein
the full-text search processor has a CPU incorporated therein.

13. A method for using the full-text search processor of claim 1, comprising the step of:
applying a world standard character code such as UTF-8 to thereby enable universal full-text search for all characters worldwide.

14. The full-text search processor of claim 1, wherein
when predetermined character codes are included in a character string of an externally given search keyword, the full-text search processor performs or does not perform the full-text search operations.

15. The full-text search processor of claim 1, wherein
by matching a part of a sentence being composed with the full-text search processor, which has therein accumulated text data that incorporates a large amount of the latest information, if there is no matching text, the full-text search processor determines that there is no precedent.

16. The full-text search processor of claim 1, wherein
when selecting an optimal recognition result among a plurality of recognition candidates of speech recognition, by matching with the full-text search processor, which has therein accumulated text data that incorporates a large amount of the latest information, and selecting terms with the most matching text, the full-text search processor improves accuracy of speech recognition.
